(19) United States
(12) Patent Application Publication
(10) Pub. No.: US 2022/0382154 A1
(43) Pub. Date: Dec. 1, 2022

(54) PHOTOSENSITIVE RESIN COMPOSITION, DRY FILM, CURED MATERIAL AND ELECTRONIC COMPONENT

(71) Applicant: TAIYO HOLDINGS CO., LTD., Hiki-gun (JP)

(72) Inventors: Maho AKIMOTO, Hiki-gun (JP); Mei KUNITO, Hiki-gun (JP); Toshiyuki OGATA, Hiki-gun (JP)

(73) Assignee: TAIYO HOLDINGS CO., LTD., Hiki-gun (JP)

(21) Appl. No.: 17/766,101

(22) PCT Filed: Sep. 17, 2020
(86) PCT No.: PCT/JP2020/035255

§ 371 Date: Apr. 1, 2022

(30) Foreign Application Priority Data
Oct. 3, 2019 (JP) 2019-183178
Oct. 3, 2019 (JP) 2019-183196

(51) Int. Cl. G03F 7/038; G03F 7/085; G03F 7/022

(52) U.S. Cl. CPC G03F 7/0387; G03F 7/085; G03F 7/022

(57) ABSTRACT

[Problem] To provide a photosensitive resin composition having high dissolution rate in the exposed area and excellent dissolution contrast (resolution).

[Solution] (A) a polyimide precursor which is a reaction product of diamine compound and dicarboxylic acid and (B) a photosensitive agent, the diamine compound comprising at least one selected from the group consisting of compounds represented by the formulae (1) and (2):

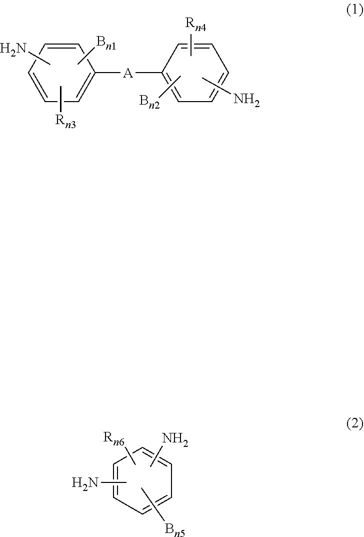

### CROSS-REFERENCE TO RELATED APPLICATION

This application is based upon and claims the benefit of priority from prior Japanese patent applications, Japanese Patent Application No. 2019-183178 (filing date: Oct. 3, 2019) and Japanese Patent Application No. 2019-183196 (filing date: Oct. 3, 2019), which are incorporated herein by reference in its entirety.

### FIELD OF THE INVENTION

The present invention relates to a photosensitive resin composition containing a polyimide precursor whose polymerization component is a diamine compound having a specific structure, a dry film comprising a resin layer formed by the photosensitive resin composition, a cured material formed of the photosensitive resin composition, and electronic component such as printed circuit board and semiconductor device using the cured material.

### BACKGROUND ART

Photosensitive resin compositions containing polyimide precursors exhibit excellent properties such as insulation, heat resistance, and mechanical strength and thus they are widely used in various fields. For example, it is tried to apply them to flexible printed circuit boards, buffer coat films for semiconductor devices, and insulating films for a rewiring buildup layer of wafer level packages (WLP).

Specifically, a cured film can be obtained by coating an alkali-developable photosensitive resin composition on a substrate and drying it to form a coating film, subsequently exposing through a pattern mask and alkali-developing by the difference in solubility of the exposed and unexposed portions in the alkaline developing solution to form a film with the desired pattern, and then heating the film to cause a ring-closing reaction of the polyimide precursor contained in the photosensitive resin composition.

In response to demand for higher functionality and smaller size in recent semiconductor devices, it is required to form a cured film with finer patterns in buffer coat film and insulating film for rewiring buildup layers in wafer-level packages, and photosensitive resin compositions are also required to have high resolution.

In order to achieve excellent resolution, it is important for the coating film of a photosensitive resin composition to have a high dissolution rate in an alkaline developing solution in the exposed area (hereinafter simply referred to as “dissolution rate in the exposed area”) and a high solution resistance in an alkaline developing solution in the unexposed area. In other words, there is a need for a photosensitive resin composition having a large difference in the dissolution speed in alkaline developing solution between the exposed and unexposed areas, i.e., having a high dissolution contrast.

In response to such requirement, Patent Document 1 discloses a photosensitive polyimide resin composition containing a polyimide precursor. Patent Document 2 discloses a composition using a polybenzoxazole precursor as a photosensitive resin having high resolution with properties equivalent to polyimide resin.

In addition, since a cured film formed by photosensitive resin composition containing polyimide precursor may be warped due to ring-closing reaction of the polyimide precursor, photosensitive resin composition curable even at low temperature is proposed for suppression of warpage (Patent Document 3).

### PRIOR ART DOCUMENTS

### Patent Documents

Patent Document 1: JP 2006-267800 A
Patent Document 2: JP 2003-241377 A
Patent Document 3: JP 2018-146964 A

### SUMMARY OF THE INVENTION

### Problems to be Solved by the Invention

However, the compositions disclosed in Patent Documents 1 and 2 could not sufficiently satisfy the dissolution contrast to achieve the resolution required for recent semiconductor devices. In addition, since the composition disclosed in Patent Document 3 should contain high boiling point solvents such as N-methyl-2-pyrrolidone (NMP) and γ-butyrolactone (GBL), the composition involved a problem of residual high boiling point solvent in the cured material.

Accordingly, the main object of the present invention is to provide a photosensitive resin composition containing a polyimide precursor having excellent insulating properties, heat resistance, mechanical strength, etc., as well as excellent solubility in various solvents (hereinafter simply referred to as “solvent solubility”) and having an excellent dissolution contrast (resolution).

### Means for Solving the Problem

The inventors have focused on the fact that an excellent dissolution contrast can be achieved by increasing the dissolution rate in the exposed area and thus found that the resolvability is significantly improved in a photosensitive resin composition containing a polyimide precursor with a specific structure. In addition, the inventors have found that such polyimide precursor has high solubility in various solvents including low boiling point solvents such as 2-methoxy-1-methylethyl acetate (PGMEA) and 4-methyl-2-pentanone (MIBK). The present invention is based on such findings.

The summary of the present invention is as follows:

[1] A photosensitive resin composition comprising:

(A) a polyimide precursor which is a reaction product of diamine compound and dicarboxylic acid and

(B) a photosensitive agent,

the diamine compound comprising at least one selected from the group consisting of compounds represented by the formulae (1) and (2):

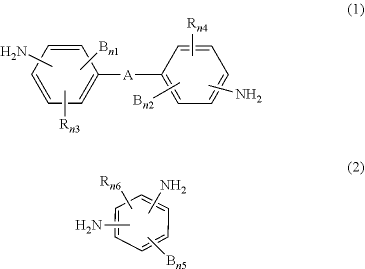

wherein

A is selected from the group consisting of single bond, O and divalent organic groups,

B is fluoroalcohol groups,

R is substituted or unsubstituted alkyl groups or substituted or unsubstituted aryl groups,

n1 and n2 are each independently integer of 0 to 4 and n1+n2 is not less than 1,

n3 and n4 are each independently integer of 0 to 3,

n5 is integer of 1 to 4, and

n6 is integer of 0 to 3, and

the dicarboxylic acid being at least one selected from the group consisting of carboxylic anhydrides and dicarboxylic chlorides.

[2] The photosensitive resin composition according to claim 1, wherein the diamine compound further comprises at least one selected from the group consisting of compounds represented by the formulae (3) and (4):

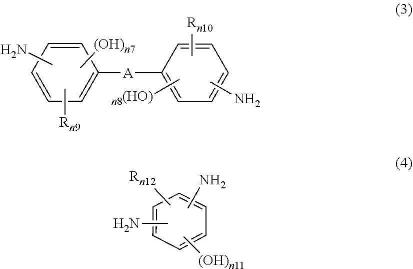

wherein

A is selected from the group consisting of single bond, O and divalent organic groups,

R is substituted or unsubstituted alkyl groups or substituted or unsubstituted aryl groups,

n7 and n8 are each dependently integer of 0 to 4 and n7+n8 is not less than 1,

n9 and n10 are each dependently integer of 0 to 3,

n11 is integer of 1 to 4, and

n12 is integer of 0 to 3.

[3] The photosensitive resin composition according to claim 1 or 2, wherein a fluorine concentration of the (A) polyimide precursor is 20 to 200 mol/g.
[4] The photosensitive resin composition according to any one of claims 1 to 3, wherein a carboxyl group concentration of the (A) polyimide precursor is 300 to 800 mol/g.
[5] The photosensitive resin composition according to any one of claims 1 to 4, wherein a hydroxyl group concentration of the (A) polyimide precursor is 200 to 600 mol/g.
[6] The photosensitive resin composition according to any one of claims 1 to 5, wherein the number of carbon of the fluoroalcohol group represented by B in the formulae (1) and (2) is each independently 1 to 10, and the number of fluorine of the fluoroalcohol group represented by B in the formulae (1) and (2) is each independently 1 to 10.
[7] The photosensitive resin composition according to any one of claims 1 to 6, further comprising an (C) adhesion agent.
[8] The photosensitive resin composition according to any one of claims 1 to 6, wherein the (B) photosensitive agent is naphthoquinone diazide compounds.
[9] A dry film comprising a film and a resin layer on the film, wherein the resin layer is formed of the photosensitive resin composition according to any one of claims 1 to 8.
[10] A cured material formed of the photosensitive resin composition according to any one of claims 1 to 8 or a resin layer of the dry film according to claim 9.
[11] An electronic component comprising at least the cured material according to claim 10.

### Effects of the Invention

According to the present invention, a photosensitive resin composition having high dissolution rate in the exposed area and excellent dissolution contrast (resolution) can be provided. Further, since the polyimide precursor contained in the photosensitive resin composition has an excellent solubility in various solvents including low boiling point solvents, the problem as above can be solved.

### DETAILED DESCRIPTION OF THE INVENTION

### [Photosensitive Resin Composition]

The photosensitive resin composition according to the present invention contains (A) a polyimide precursor and (B) a photosensitive agent as essential components, and may contain other optional components such as crosslinking agents, plasticizers, and adhesion agents. Each component of the photosensitive resin composition according to the present invention will be described below.

### <(A) Polyimide Precursor>

A polyimide precursor, which is a reaction product of diamine compound and dicarboxylic acid, contained in the photosensitive resin composition comprises at least one diamine compound selected from the group consisting of compounds represented by the formulae (1) and (2).

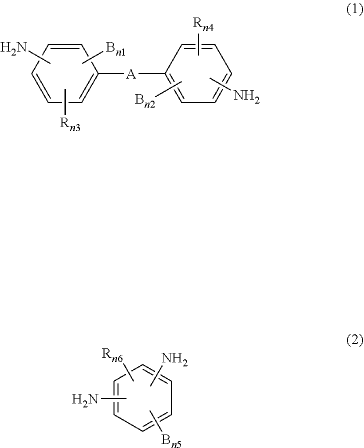

In one embodiment of the present invention, it is preferable to use at least one diamine compound selected from the diamine compounds represented by the above general formulae (1) and (2) and at least one diamine compound selected from the diamine compounds represented by the following general formulae (3) and (4) together as the diamine compound.

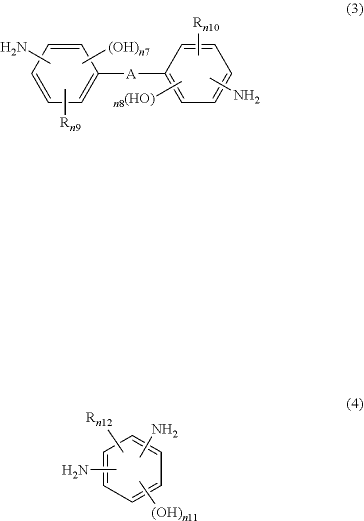

In the above general formulae (1) and (3), A is selected from the group consisting of single bond, O and divalent organic groups.

The number of carbons in the divalent organic group is preferably 1 to 10, more preferably 1 to 6, further preferably 1 to 3.

Examples of the divalent organic group include alkylene groups, cycloalkylene groups, arylene groups and alkyl ether groups, ketone groups, ester groups and the like.

More specifically, examples of the divalent organic group include, but are not limited to, the followings. The expressions “a” in the structure are each independently integer of 0 to 2, preferably 0 to 1, in particularly preferably 0 in view of solvent solubility. Further, the expressions “b” in the structure are integer of 1 to 3, preferably 2 to 3, in particularly preferably 3 in view of solvent solubility and transparency of a cured material. Furthermore, the expression “*” represents a bond.

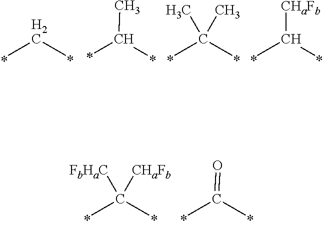

In the above general formulae (1) and (2), B is a fluoroalcohol group.

The number of carbons in the fluoroalcohol group is each independently preferably 1 to 10, and more preferably 3 to 6.

The number of fluorine in the fluoroalcohol group is each independently preferably 1 to 10, and more preferably 4 to 8. Solvent solubility and transparency of the cured material can be improved in such range.

Specifically, examples of the fluoroalcohol group include, but are not limited to, groups having a following structure. The expression “*” represents a bond.

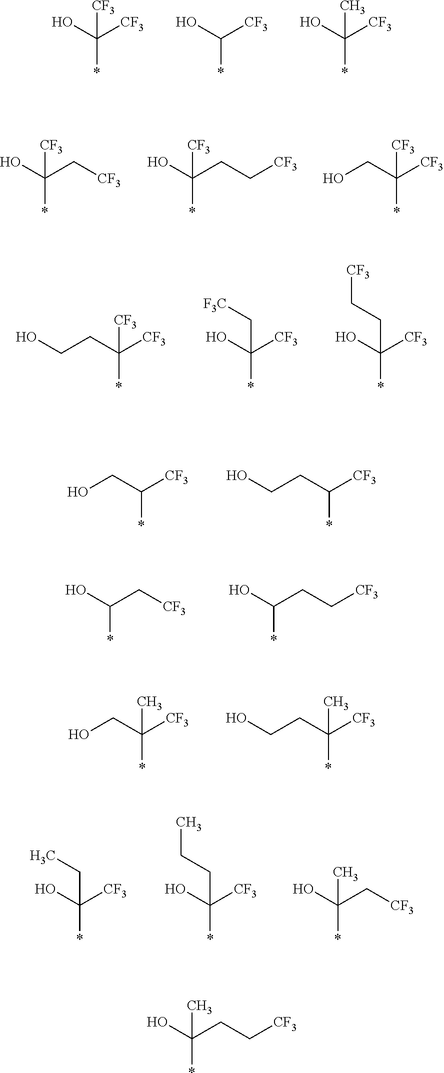

In the above general formulae (1) to (4), R is substituted or unsubstituted alkyl groups or substituted or unsubstituted aryl groups.

The number of carbons in the alkyl group is preferably 1 to 10, more preferably 1 to 6.

Examples of the alkyl group include methyl group, ethyl group, n-propyl group, isopropyl group, n-butyl group, tert-butyl group, n-pentyl group, sec-pentyl group, n-hexyl group, cyclohexyl group, fluoromethyl group, difluoromethyl group, trifluoromethyl group, chloromethyl group, dichloromethyl group, trichloromethyl group, bromomethyl group, dibromomethyl group, tribromomethyl group, fluoroethyl group, difluoroethyl group, trifluoroethyl group, chloroethyl group, dichloroethyl group, trichloroethyl group, bromoethyl group, dibromoethyl group, tribromoethyl group, hydroxymethyl group, hydroxyethyl group, hydroxyl propyl group, methoxy group, ethoxy group, n-propoxy group, n-butoxy group, n-pentyloxy group, sec-pentyloxy group, n-hexyloxy group, cyclohexyloxy group, n-heptyloxy group, n-octyloxy group, n-nonyloxy group, n-decyloxy group, trifluoromethoxy group, methylamino group, dimethylamino group, trimethylamino group, ethylamino group, propylamino group and the like.

Examples of the aryl group include phenyl group, naphthyl group, ametryl group, pyrenyl group, phenanthrenyl group, biphenyl group and the like.

Examples of the substituent include alkyl group, alkyl group with halogen such as fluoro group, chloro group and like, halogen group, amino group, nitro group, hydroxyl group, cyano group, carboxyl group, sulfone group and the like.

In the above general formulae (1), n1 and n2 are each independently integer of 0 to 4, preferably integer of 1 to 2. And n1+n2 is not less than 1.

In the above general formulae (1), n3 and n4 are each independently integer of 0 to 3, preferably integer of 0 to 1.

In the above general formulae (2), n5 is integer of 1 to 4, preferably integer of 1 to 2.

In the above general formulae (2), n6 is integer of 0 to 3, preferably integer of 0 to 1.

In the above general formulae (3), n7 and n8 are each independently integer of 0 to 4, preferably integer of 1 to 2. And n7+n8 is not less than 1.

In the above general formulae (3), n9 and n10 are each independently integer of 0 to 3, preferably integer of 0 to 1.

In the above general formulae (4), n11 is integer of 1 to 4, preferably integer of 1 to 2.

In the above general formulae (4), n12 is integer of 0 to 3, preferably integer of 0 to 1.

Examples of diamine compounds satisfying the above general formulae (1) include, but are not limited to, the followings.

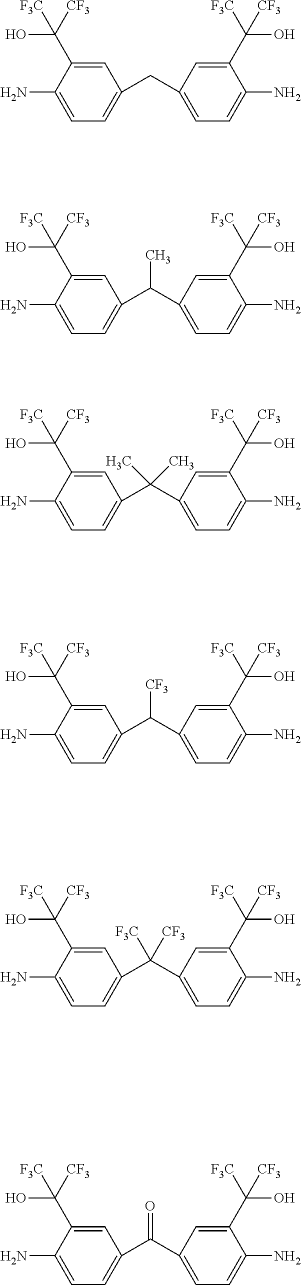

Examples of diamine compounds satisfying the above general formulae (2) include, but are not limited to, the followings.

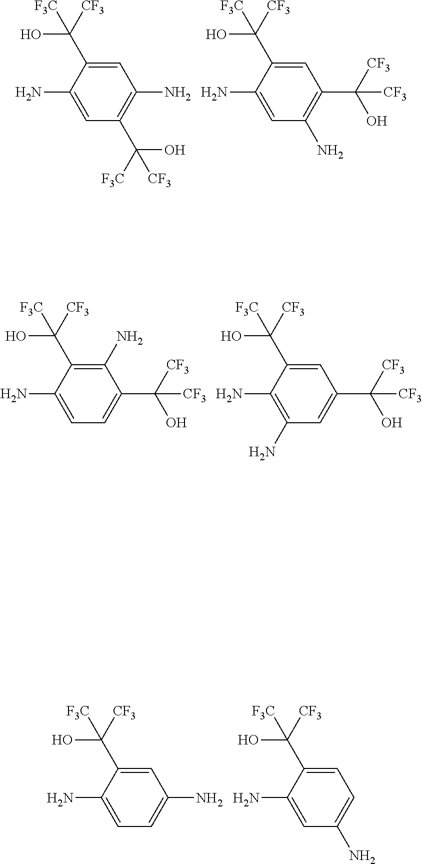

Examples of diamine compounds satisfying the above general formulae (3) include, but are not limited to, the followings.

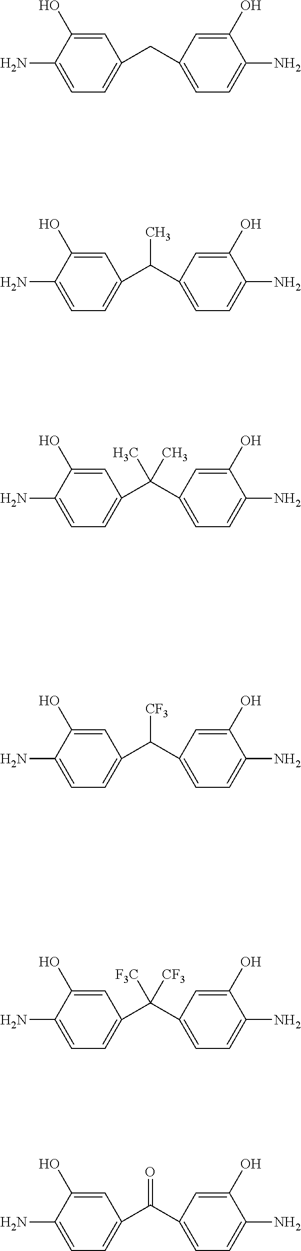

Examples of diamine compounds satisfying the above general formulae (4) include, but are not limited to, the followings.

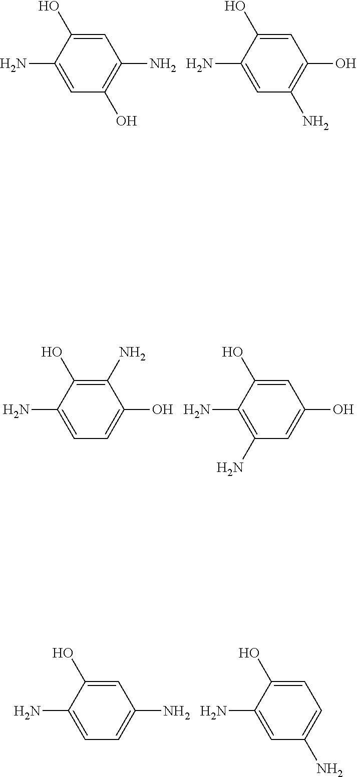

The composition ratio of diamine compounds represented by the general formulae (1) and the general formulae (2) to polyimide precursor is preferably 5 to 40 mol %, and more preferably 15 to 35 mol %, in view of the adjustment of dissolving speed in the development and improvement in rate of ring closure in low temperature curing. The effects of the present invention can be expected by adopting this composition ratio of polyimide precursor to diamine compounds.

The composition ratio of diamine compounds represented by the general formulae (3) and the general formulae (4) to polyimide precursor is preferably 10 to 45 mol %, and more preferably 15 to 35 mol %, in view of the adjustment of dissolving speed in the development and improvement in rate of ring closure in low temperature curing.

The carboxylic anhydrides that compose the polyimide precursor is preferably represented by the following general formulae (5).

(A) The carboxylic anhydrides that compose the polyimide precursor polyimide precursor is at least one selected from the group consisting of carboxylic anhydrides and dicarboxylic chlorides.

The carboxylic anhydrides represented by the following general formula (5) may be used preferably.

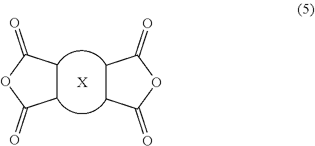

In above general formulae (5), X is tetravalent organic groups.

Examples of tetravalent organic groups include, but are not limited to, the following structures.

The expressions “a” in the structure are each independently selected from integer of 0 to 2, preferably 0 to 1, in particularly preferably 0 in view of solvent solubility. Further, the expressions “b” in the structure are integer of 1 to 3, preferably 2 to 3, in particularly preferably 3 in view of solvent solubility and transparency of a cured material. Furthermore, the expression “*” represents a bond.

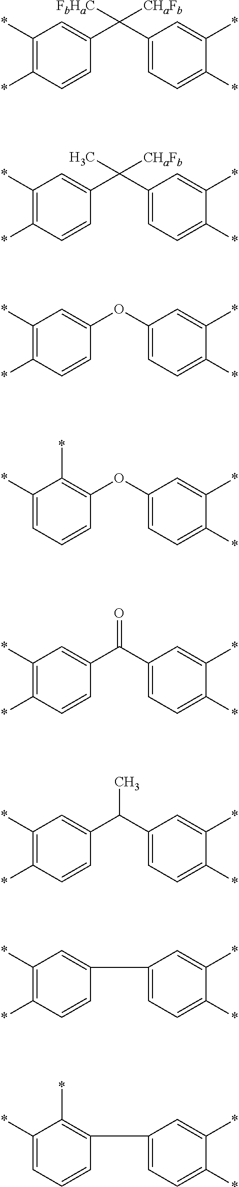

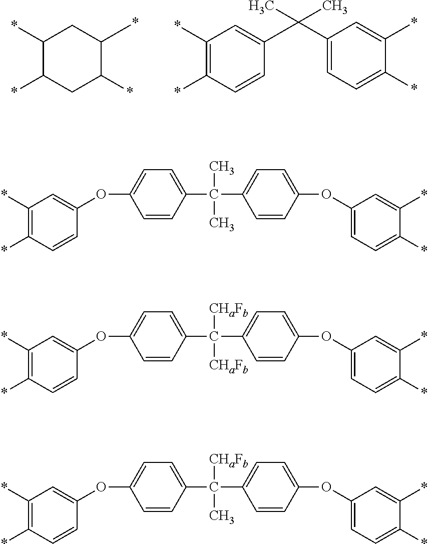

Specific examples of tetravalent organic groups with the above preferred structure include, but are not limited to, the followings.

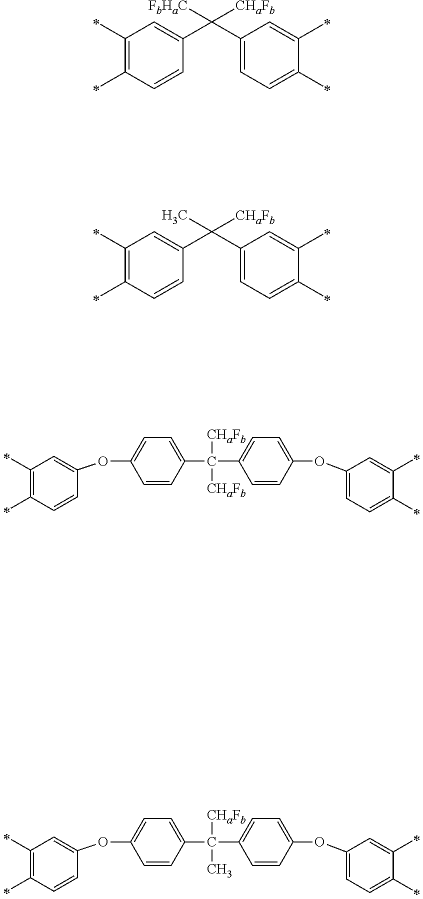

Specific examples of tetravalent organic groups with the above preferred structure include, but are not limited to, the followings.

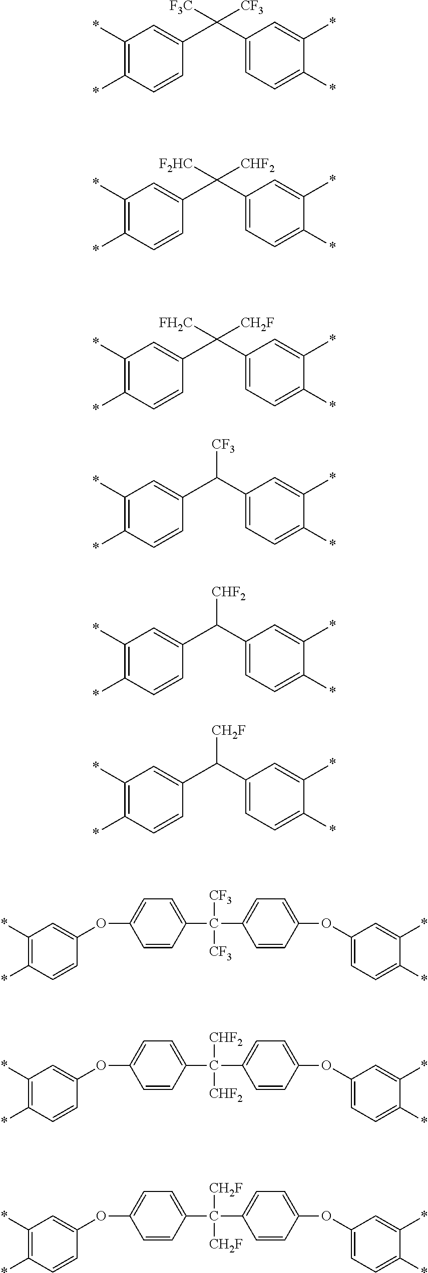

Among the tetravalent organic groups mentioned above, the groups with following structure are preferably in view of dissolving speed of exposed area and dissolving contrast.

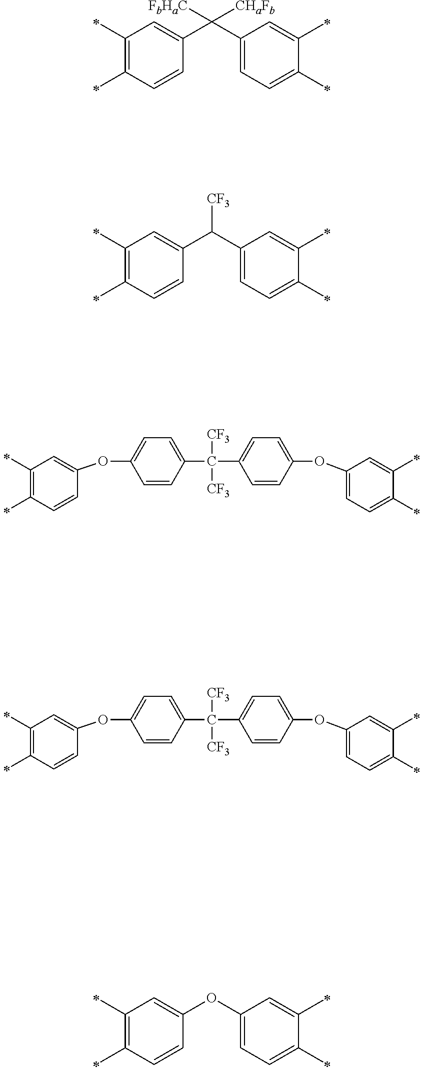

The composition ratio of carboxylic anhydrides to polyimide precursor is preferably 0 to 40 mol %, and more preferably 0 to 35 mol %. Dissolving speed of exposed are can be promoted and resolution can be improved.

The dicarboxylic chlorides are preferably represented by the following general formula (6).

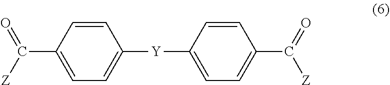

In the above general formula (6), Y is selected from the group consisting of single bond, O and divalent organic groups. The divalent organic groups mentioned above can be used.

In the above general formula (6), Z is halogen atom, preferably chloride.

The composition ratio of dicarboxylic chlorides to polyimide precursor is preferably 10 to 50 mol %, and more preferably 15 to 50 mol % in view of inhibition of dissolving speed of unexposed part.

The photosensitive resin composition according to the present invention may contain another reactive component as long as the properties thereof are not impaired.

As one embodiment, polyimide precursor which is a reaction product of diamine compound and dicarboxylic acid can be represented by the following general formulae (7) and (8). A, B, R, X, n1 to n6 are same as the above definition.

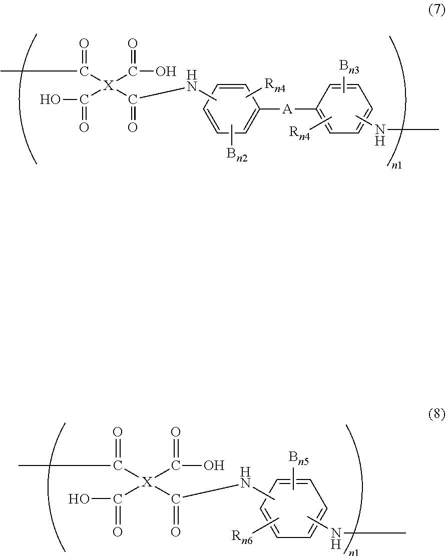

Examples of structure satisfying the above general formulae (7) and (8) include, but are not limited to, the following.

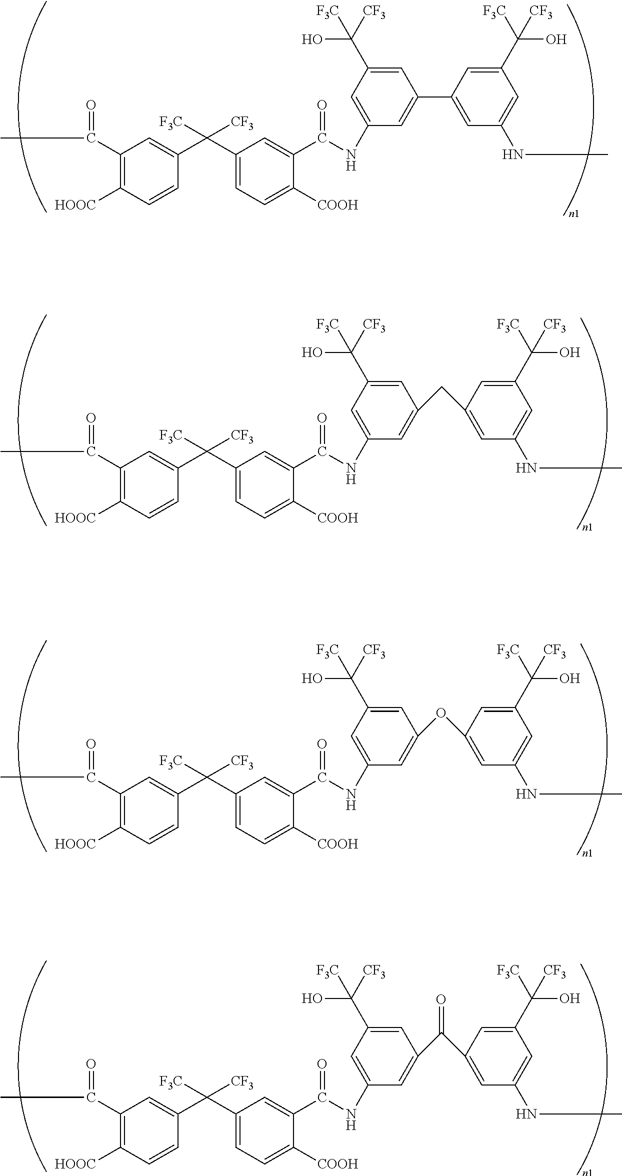

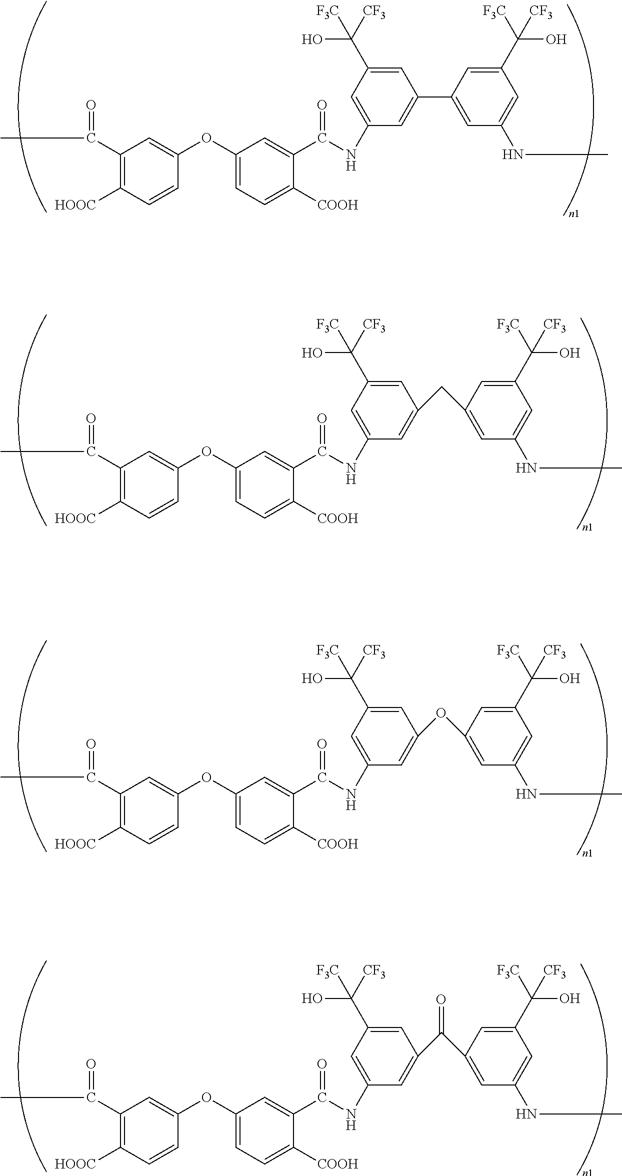

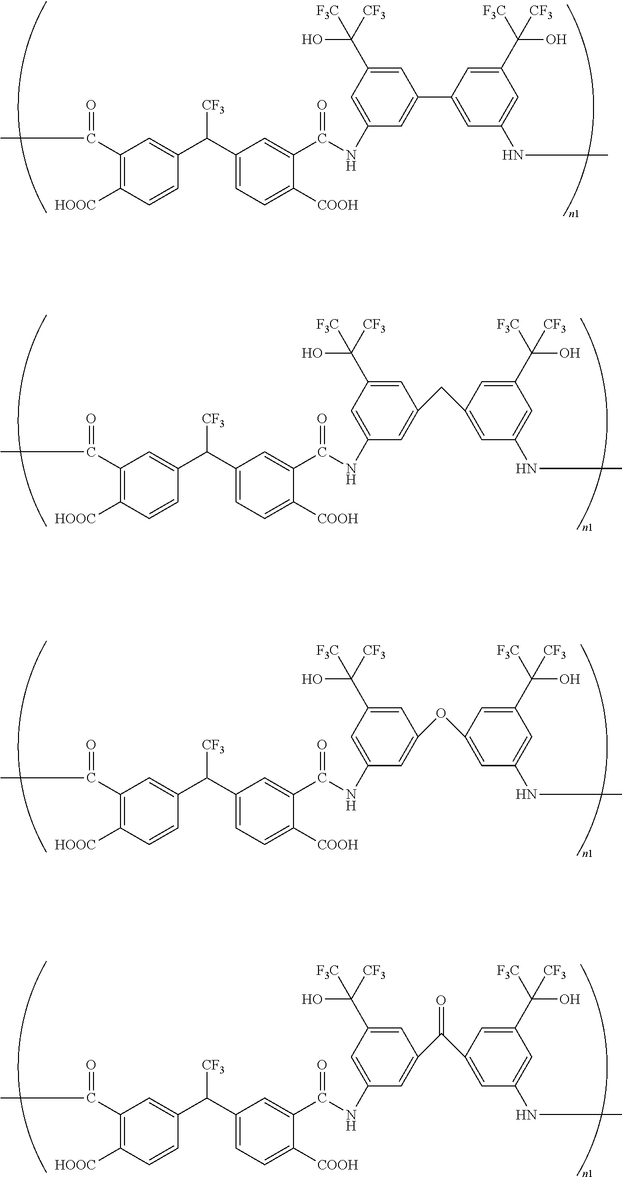

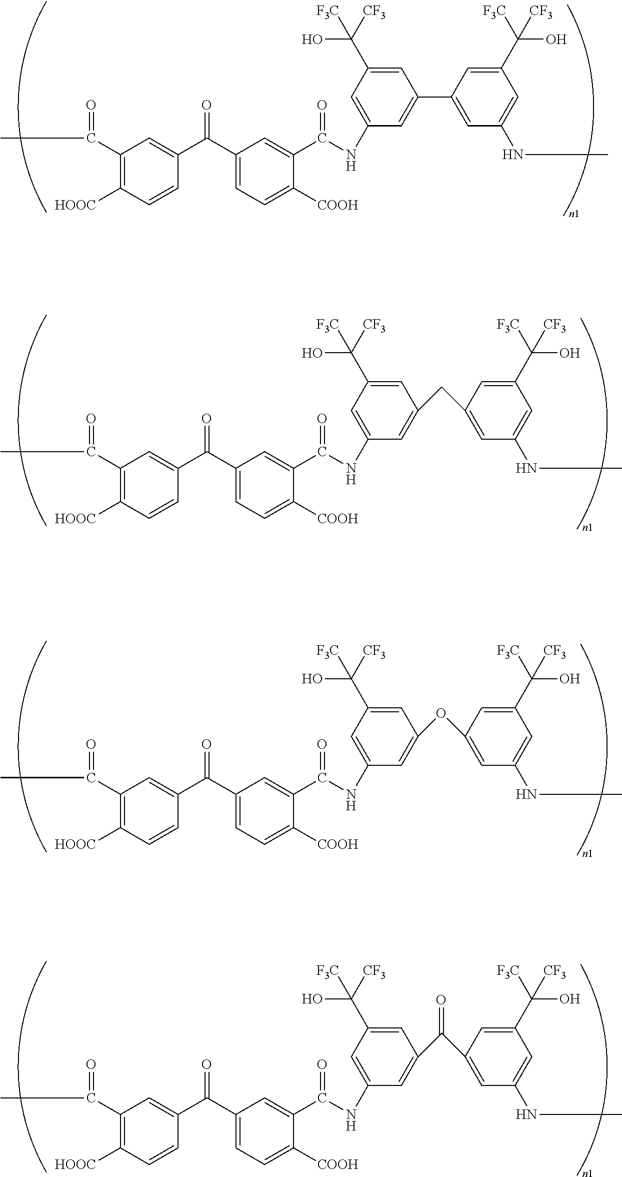

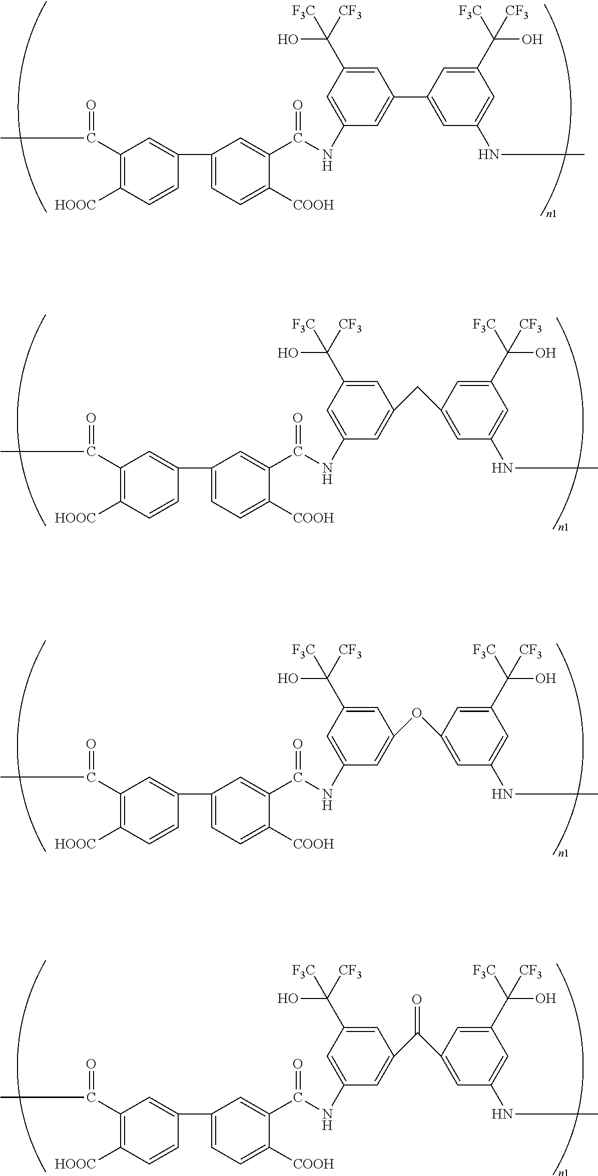

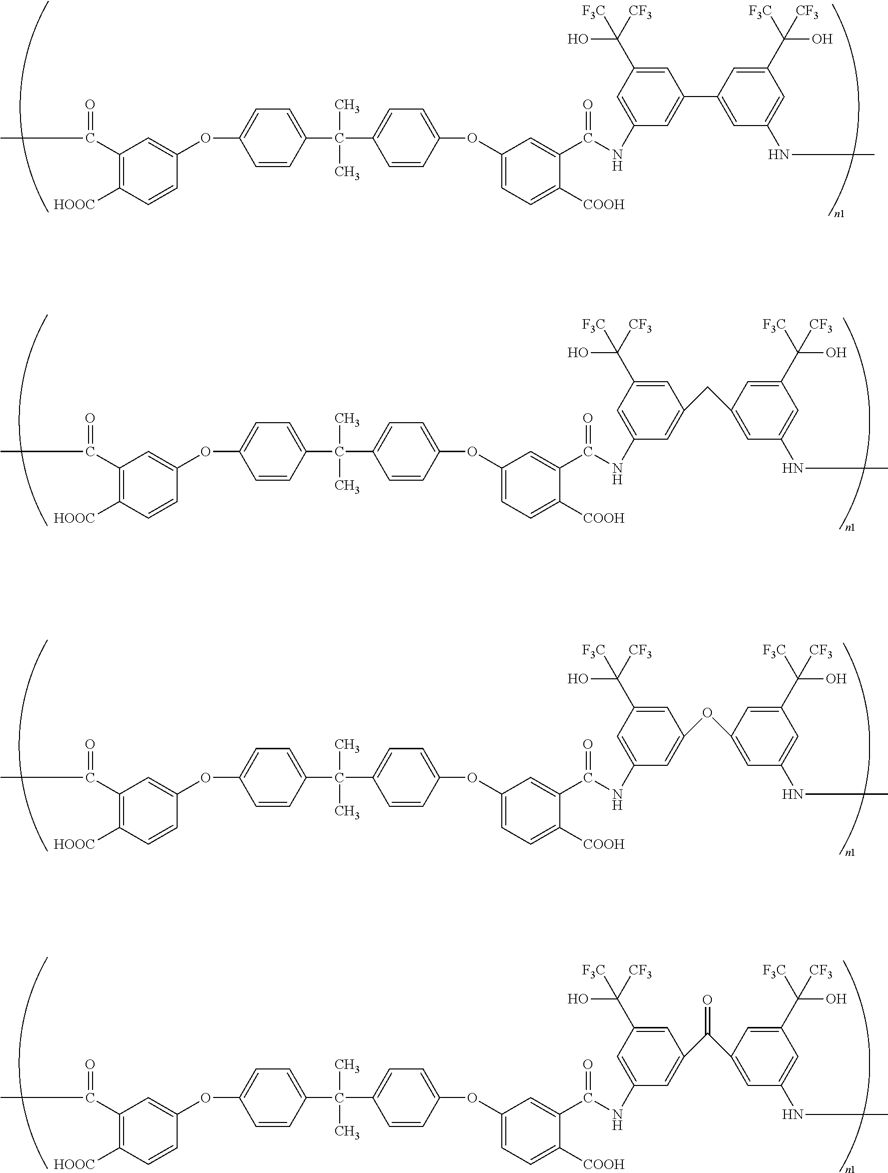

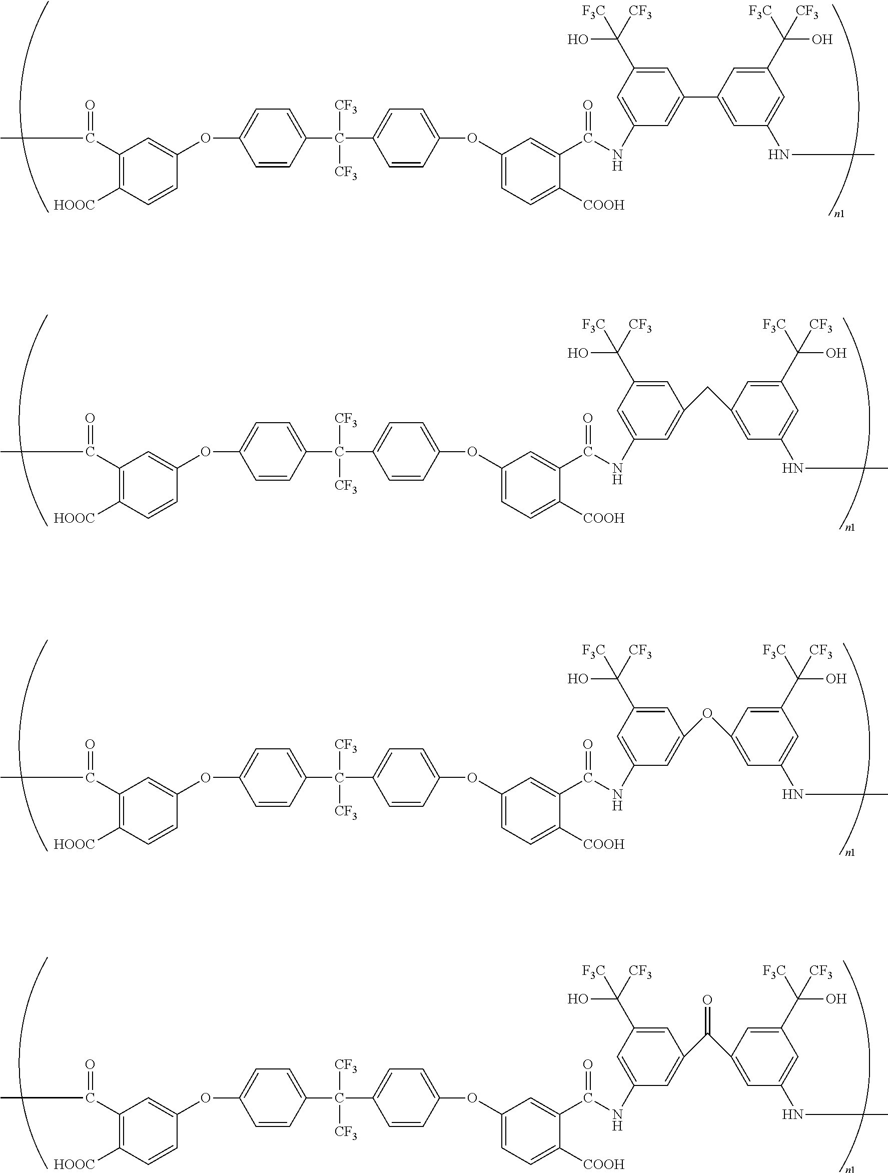

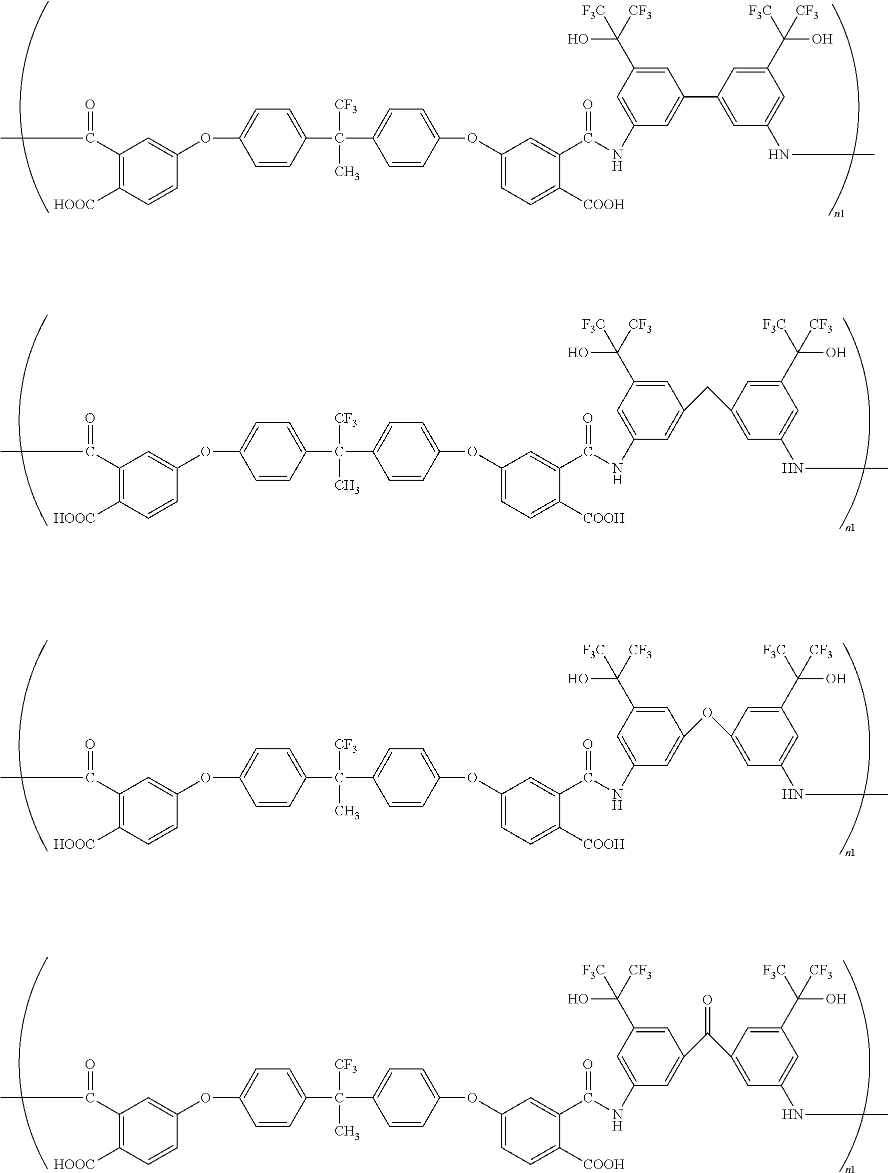

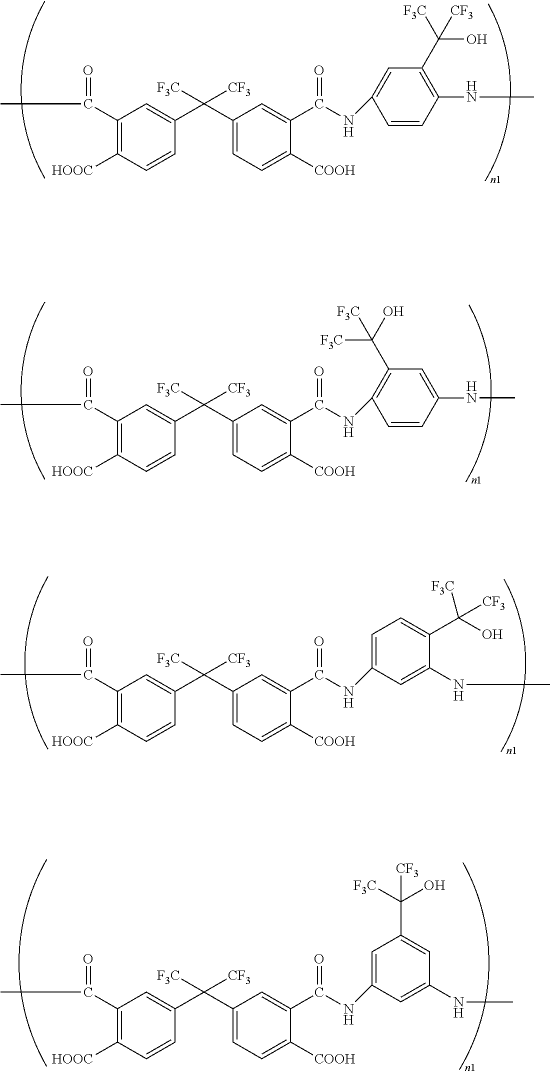

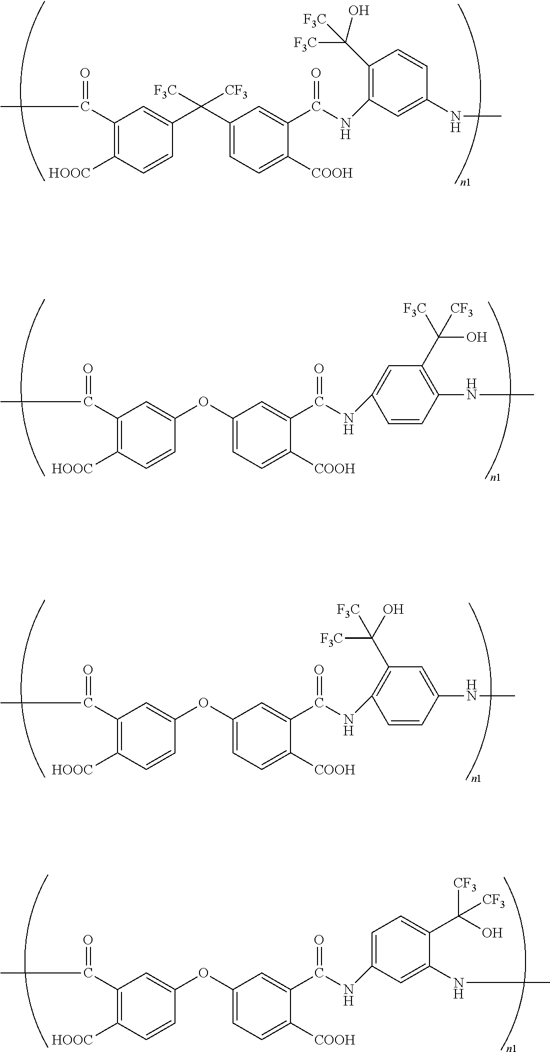

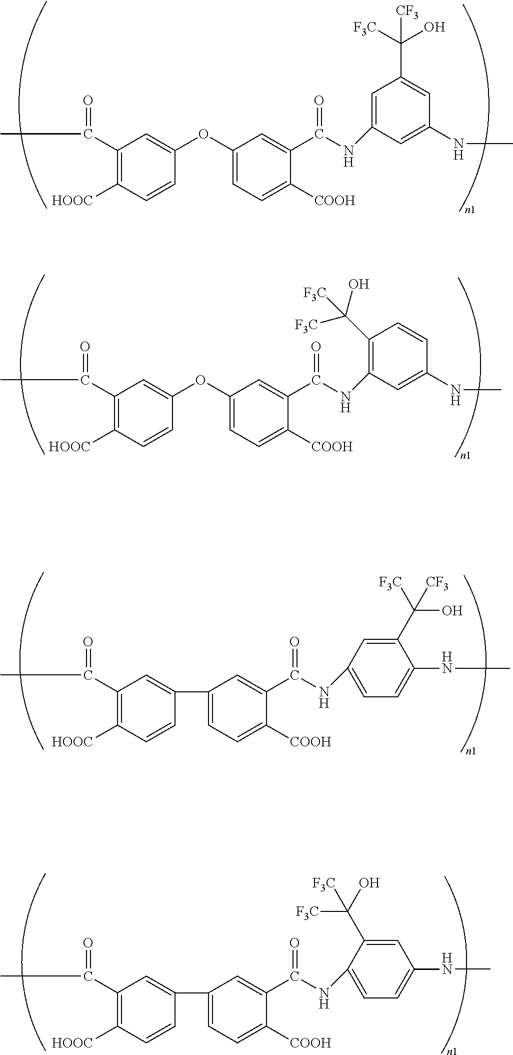

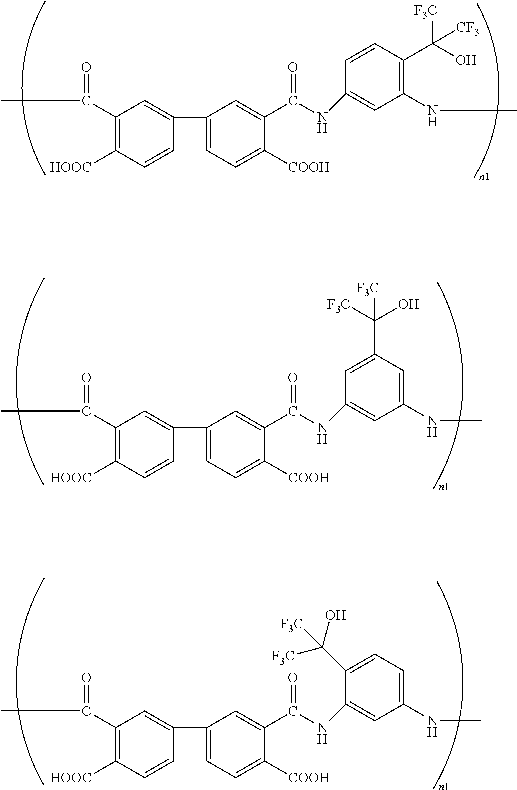

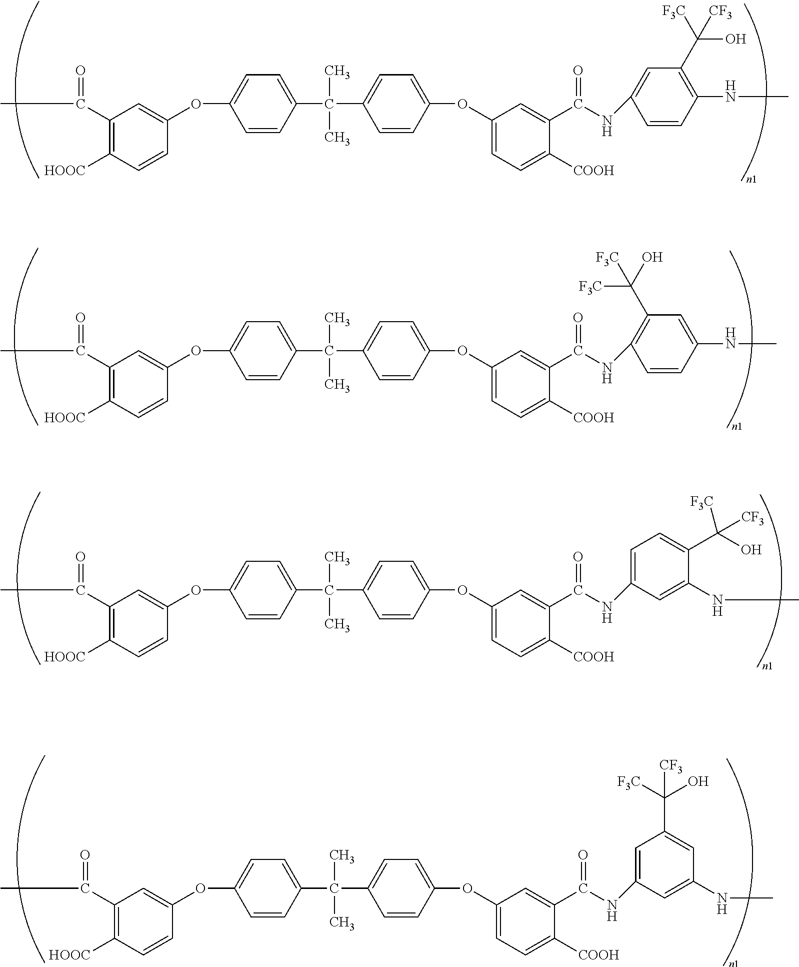

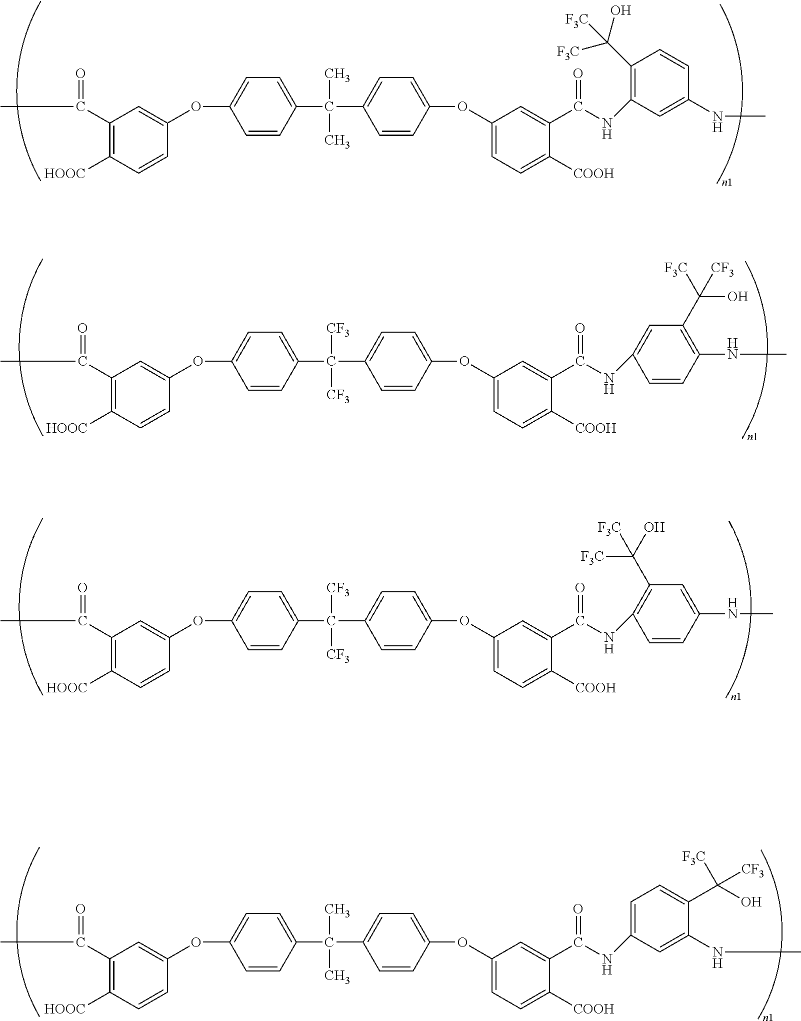

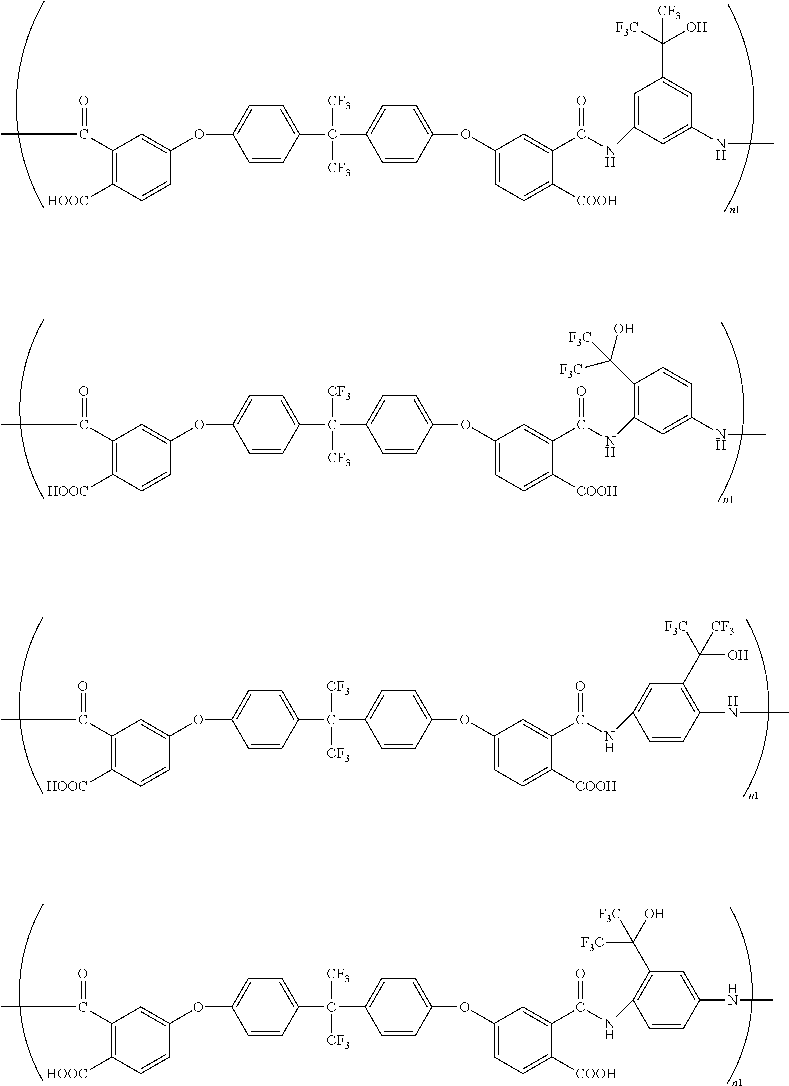

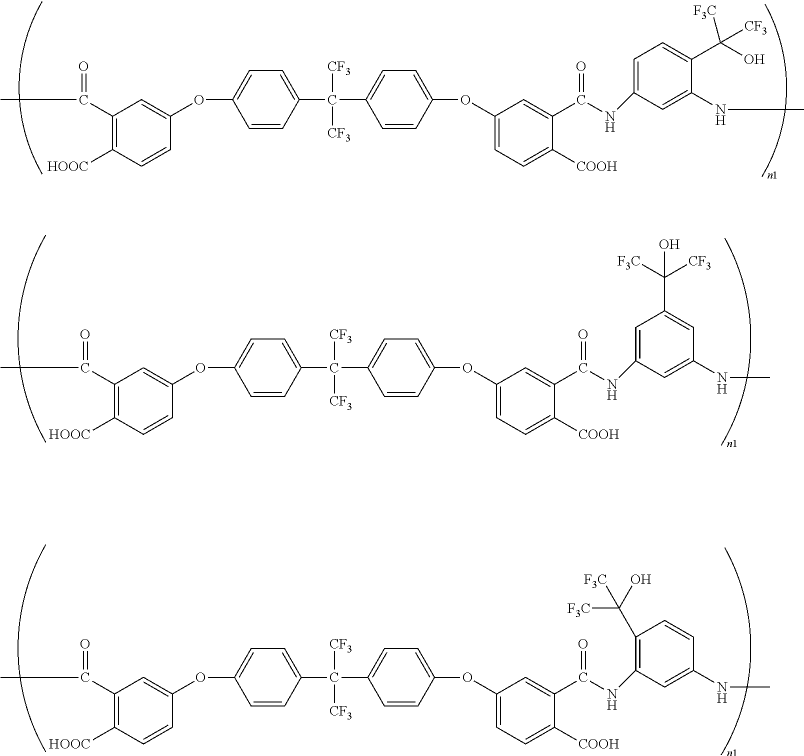

The number average molecular weight (Mn) of the polyimide precursor which is a reaction product (copolymer) of diamine compound and dicarboxylic acid is preferably 2,000 to 30,000 and more preferably 5,000 to 10,000 in view of the balance between solubility of the exposed part in the alkaline developing solution and solution resistance of the unexposed portions in the alkaline developing solution. Also, the weight average molecular weight (Mw) of the polyimide precursor is preferably 4,000 to 80,000 and more preferably 10,000 to 30,000 in view of suppression of crack in cured material. Moreover, Mw/Mn is preferably 2.0 to 4.0 and more preferably 2.3 to 3.0 in view of reducing the residue and swelling generated during development. Furthermore, in the present specification, the number average molecular weight and weight average molecular weight are determined by gel permeation chromatography and converted with standard polystyrene.

The glass transition temperature (Tg) of polyimide which is a product of ring-closing reaction is preferably 180° C. or more, more preferably 200° C. or more in view of heating resistance when cured.

Furthermore, in the present specification, Tg is measured in accordance with JIS K 7121 using Differential Scanning calorimetry (DSC).

The concentration of carboxyl group in polyimide precursor is preferably 300 to 800 mol/g, more preferably 300 to 600 mol/g in view of dissolution rate in the exposed area and dissolution contrast.

The concentration of hydroxyl group in polyimide precursor is preferably 200 to 600 mol/g, more preferably 300 to 500 mol/g in view of dissolution rate in the exposed area and dissolution contrast.

The concentration of fluorine in polyimide precursor is preferably 20 to 200 mol/g, more preferably 50 to 100 mol/g in view of solvent solubility and transparency of a cured product.

The photosensitive resin composition according to the present invention may partially contain the ring-closed structure of the polyimide precursor described above as long as the properties thereof are not impaired but imidization rate is preferably 50% or less, more preferably 40% or less, further preferably 20% or less in view of solution resistance of the unexposed portions in the alkaline developing solution.

The photosensitive resin composition may also contain other polymerizable components excluding diamine compound and dicarboxylic acid described above.

(A) polyimide precursor can be produced by a conventionally known method using a diamine compound and dicarboxylic acid described above.

### <(B) Photosensitive Agent>

The photosensitive resin composition according to the present invention contains a photosensitive agent. It is possible to adjust the solubility of the photosensitive resin composition in the alkaline developing solution by containing a photosensitive agent. Examples of photosensitive agent includes photoacid generator and photobase generator. Among these photosensitive agent, photoacid generator is preferable in view of dissolution contrast.

Content of photosensitive agent can be adjusted suitably but for example the photoacid generator is 0.1 to 30 pts. Mass, preferably 1 to 20 based on 100 pts. Mass of polyimide precursor. Two or more types of photosensitive resin composition may be contained.

The photoacid generator is a compound that generates an acid by being exposed to light such as ultraviolet light or visible light. Examples of photoacid generator include naphthoquinone diazide compounds, diarylsulfonium salts, triarylsulfonium salts, dialkylphenacylsulfonium salts, diaryliodonium salts, aryldiazonium salts, aromatic tetracarboxylic acid ester, aromatic sulfonic acid ester, nitrobenzyl esters, aromatic N-oxyimidosulfonates, aromatic sulfamides, and benzoquinone diazosulfonic acid ester and these may be used alone or in combination. Among these, naphthoquinone diazide compounds are preferable in view of dissolution contrast.

Examples of naphthoquinone diazide compounds include specifically, naphthoquinone diazide addition product of tris(4-hydroxyphenyl)-1-ethyl-4-isopropylbenzene (for example, TS533, TS567, TS583 and TS593 manufactured by Sanbo Chemical Ind. Co., Ltd.), naphthoquinone diazide addition product of tetrahydroxybenzophenone (for example, BS550, BS570 and BS599 manufactured by Sanbo Chemical Ind. Co., Ltd.), and naphthoquinone diazide addition product of 4-{4-[1,1-bis(4-hydroxyphenyl)ethyl]-α,α-dimethylbenzyl} phenol (for example TKF-428 and TKF-528 manufactured by Sanbo Chemical Ind. Co., Ltd.)

The photobase generator is a kind of compounds that generates one or more types of basic substance (secondary amine and tertiary amine etc.) by changing the molecular structure or by cleavage of the molecule upon light irradiation, such as ultraviolet light or visible light.

The photobase generator can be an ionic photobase generator or a non-ionic photobase generator, but ionic photobase generator is preferable in view of sensitivity of the photosensitive resin composition.

Examples of ionic photobase generators include carboxylic acid containing aromatic component and tertiary amine etc., commercial products such as ionic PBG WPBG-082, WPBG-167, WPBG-168, WPBG-266 and WPBG-300 can be used.

Examples of non-ionic photobase generators include α-aminoacetophenone compounds, oxime ester compounds, and compounds with substituents such as N-formylated aromatic amino groups, N-acylated aromatic amino groups, nitrobenzylcarbamate groups, alkoxybenzylcarbamate groups and the like.

Other photobase generators include WPBG-018 (product name: 9-anthrylmethyl N,N′-diethylcarbamate), WPBG-027 (product name: (E)-1-[3-(2-hydroxyphenyl)-2-propenoyl] piperidine), WPBG-140 (product name: 1-(anthraquinon-2-yl) ethyl imidazolecarboxylate) and WPBG-165, etc. those are manufactured by Wako Pure Chemical Co.

### [Cross-Linking Agent]

The photosensitive resin composition according to the present invention may contain a cross-linking agent. The addition of a cross-linking agent can lower the curing temperature of the photosensitive resin composition. The cross-linking agent is not limited, and any well-known and common type of cross-linking agent can be used. But a compound that can react with the carboxyl groups in the polyimide precursor to form a cross-linked structure is preferable.

Examples of compounds that react with polyimide precursors or hydroxyl group in polyimide include cross-linking agents with cyclic ether groups such as epoxy group and the like and cyclic thioether groups such as episulfide group and the like, cross-linking agents with an alcoholic hydroxyl group that is an alkylene group with 1-12 carbons bonding to hydroxyl group such as a methylol group and the like, compounds with an ether bond such as alkoxymethyl group, and the like, cross-linking agent with triazine ring structure and urea cross-linking agent and these may be used alone or in combination. Among these, cross-linking agent with a cyclic ether group, especially an epoxy group, and cross-linking agent with an alcoholic hydroxyl group, especially a methylol group bonding to hydroxyl group, are preferable.

Among these cross-linking agents described above, cross-linking agent with epoxy group thermally react with polyimide precursors or hydroxyl groups of polyimides to form a cross-linking structure. Functional group number of cross-linking agents with epoxy group is preferably 2 to 4. Low temperature curability can be achieved and the dissolution contrast of the formed coating film can be further improved by containing cross-linking agents with epoxy group in the photosensitive resin composition.

Among the cross-linking agents with epoxy group, epoxy compound with two or more functional groups having naphthalene skeleton is preferable. Not only superior insulating films can be obtained by flexibility and chemical resistance, but also low CTE (Coefficient Thermal Expansion), which is in an antinomy relationship with flexibility, can be achieved and wrap or crack of insulating films can be suppressed. Bisphenol A epoxy compounds are preferably usable in view of flexibility

As a cross-linking agent with methylol group, it is preferable to have two or more methylol groups, and it is further preferable to be a compound represented by the following general formula (9).

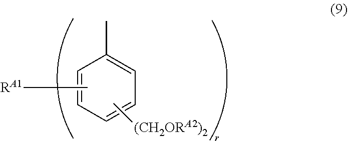

In the above formula, R^{A1} represents 2 to 10-valent organic group, preferably an alkylene group with 1 to 3 carbons that may have substituents. R^{A2} is each independently represents a hydrogen atom or an alkyl group having 1 to 4 carbons, preferably a hydrogen atom. r represents an integer of 2 to 10, preferably an integer of 2 to 4, and more preferably 2.

Furthermore, the cross-linking agent with methylol group preferably has a fluorine atom, more preferably has a trifluoromethyl group. The fluorine atom or trifluoromethyl group described above are preferably possessed by 2 to 10-valent organic group represented by R^{A1} in the general formula (9) and R^{A1} is preferably di(trifluoromethyl)methylene group. The cross-linking agent with methylol group preferably has a bisphenol structure, and more preferably has a bisphenol AF structure.

Compounded amount of cross-linking agent is 0.1 to 30 parts by mass, preferably is 0.1 to 20 parts by mass, relative to 100 parts by mass of the nonvolatile component of the polyimide precursor.

### [Plasticizer]

The photosensitive resin composition according to the present invention may contain a plasticizer. Plasticizing effect, i.e., reducing the cohesive reaction between polymer molecular chains, improving the intermolecular mobility and flexibility, and as a result, improving the thermal molecular motion of the polyimide precursor and accelerating the cyclization reaction, thereby providing low temperature curability to the photosensitive resin composition by containing a plasticizer.

Plasticizer is not limited as long as that is a compound that improve plasticity and examples of plasticizer include bifunctional (meth)acrylic compounds, sulfonamide compounds, phthalate compounds, maleate compounds, aliphatic dibasic acid esters, phosphate esters, ether compounds such as crown ethers, and the like. Plasticizer may be used alone or in a combination of more than one type.

Among these, bifunctional (meth)acrylic compounds are preferable. The bifunctional (meth)acrylic compounds are preferable because that does not form a cross-linked structure with other components in the composition. The bifunctional (meth)acrylic compounds that form a linear structure by self-polymerization are preferable in view of further relaxing the internal stress of the cured product.

Among bifunctional (meth)acrylic compounds, di(meth)acrylates that is an alkylene oxide (such as ethylene oxide or propylene oxide) adduct of diol or bifunctional polyester (meth)acrylates is preferable. The bifunctional polyester (meth)acrylates are more preferable.

As a di(meth)acrylates that is an alkylene oxide adduct of diol, specifically diols modified with alkylene oxide followed by terminal addition of (meth)acrylate are preferable, and diols with aromatic rings are more preferred. For example, diacrylates that is EO (ethylene oxide) adduct of bisphenol A, specifically diols, diacrylates that is PO (propylene oxide) adduct of bisphenol A, specifically diols and the like.

The specific structure of di(meth)acrylates that is an alkylene oxide adduct of diol is shown in general formula (10) below but is not limited to this.

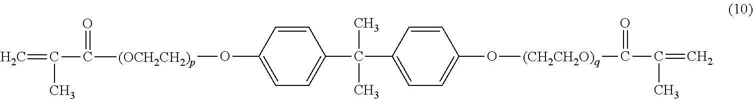

In the above formula, p+q is 2 or more, preferably 2 to 40, more preferably 3.5 to 25.

Compounded amount of plasticizer is not particularly limited but preferably 3 to 40 parts by mass per 100 parts by mass of the nonvolatile component of the polyimide precursor.

### [(C) Adhesion Agent].

The photosensitive resin composition according to the present invention preferably contain an adhesive agent. The adhesion to substrate can be improved by containing an adhesion agent. Adhesive agents that can be used include silane coupling agents, titanate coupling agents and aluminum coupling agents.

Examples of silane coupling agent include, N-phenyl-3-aminopropyltrimethoxysilane, γ-methacryloxypropyltrimethoxysilane, γ-methacryloxypropyltriethoxysilane, γ-acryloxypropyltrimethoxysilane, γ-acryloxypropyltriethoxysilane, γ-mercaptopropyltrimethoxysilane, γ-aminopropyltriethoxysilane, 3-ureidopropyltrialkoxysilane, and phenyltrimethoxysilane etc.

Examples of titanate coupling agent include, isopropyl triisostearoyl titanate, isopropyl tridecylbenzenesulfonyl titanate, isopropyl tris (dioctylpyrophosphate) titanate, tetraisopropyl bis (dioctylphosphite) titanate, tetraoctyl bis (ditridecyl phosphite) titanate, tetra (2,2-diallyloxymethyl) bis (ditridecyl)phosphite titanate, bis (dioctylpyrophosphate) oxyacetate titanate, bis (dioctylpyrophosphate) ethylene titanate etc.

Examples of aluminum coupling agent include, acetoalkoxyaluminum diisopropylate etc.

The adhesive agents described above may be used alone or in a combination of more than one type. Among the adhesive agents described above, N-phenyl-3-aminopropyltrimethoxysilane, γ-aminopropyltriethoxysilane and 3-ureidopropyltrialkoxysilane are preferable in view of that can improve the adhesion to substrate can be improved without adverse influence on development rate.

An amount of adhesive agents is not limited but preferably 0.1 to 10 parts by mass of the nonvolatile component relative to 100 parts by mass of polyimide precursor.

### [Thermal Acid Generators, Sensitizers and Other Components]

The photosensitive resin composition according to the present invention may further contain a known thermal acid generator to promote the cyclization reaction of the polyimide precursor and a known sensitizer to improve photosensitivity, as long as the properties thereof are not impaired. The photosensitive resin composition according to the present invention may contain various other organic or inorganic low or high molecular weight compounds to impart processing characteristics and various functionalities. For example, known and customary surfactants, leveling agents, fine particles and the like may be used. Examples of fine particles include organic fine particles such as polystyrene and polytetrafluoroethylene, and inorganic fine particles such as silica, carbon, and layered silicates. Various colorants and fibers may also be included in the photosensitive resin composition according to the present invention.

### [Solvent]

The photosensitive resin composition according to the present invention may contain a solvent. As a solvent, any solvent that can dissolve the above-mentioned polyimide precursor may be used without any particular limitation, but take into account the residual properties of the photosensitive resin composition when the temperature of heat curing after exposure and development of the coating film is lowered, a solvent with boiling point below 200° C. is preferable.

Solvents with boiling point below 200° C. includes, propylene glycol methyl ether acetate (PGMEA), 4-methyl-2-pentanone (MIBK), N-methylcaprolactam, dimethyl sulfoxide, tetramethyl urea, pyridine, dimethyl sulfone, hexamethyl sulfoxide, ethyl acetate, butyl acetate, ethyl lactate, methyl 3-methoxypropionate, methyl 2-methoxypropionate, ethyl 3-methoxypropionate, ethyl 2-methoxypropionate, ethyl 3-ethoxypropionate, ethyl 2-ethoxypropionate, ethylene glycol dimethyl ether, diethylene glycol dimethyl ether, diethylene glycol diethyl ether, diethylene glycol methyl ethyl ether, propylene glycol dimethyl ether, dipropylene glycol dimethyl ether, ethylene glycol monomethyl ether, ethylene glycol monoethyl ether, diethylene glycol monomethyl ether, diethylene glycol monoethyl ether, propylene glycol monomethyl ether, propylene glycol monoethyl ether, dipropylene glycol monomethyl ether, dipropylene glycol monoethyl ether, propylene glycol monomethyl ether acetate carbitol acetate, ethyl cellosolve acetate, cyclohexanone, methyl ethyl ketone, methyl isobutyl ketone, and 2-heptanone. Solvent may be used alone or in a combination of more than one type.

An amount of solvent in the photosensitive resin composition can be changed according to the application without any particular limitation. For example, the amount of solvent can be 200 to 2000 parts by mass relative to 100 parts by mass of polyimide precursor contained in the photosensitive resin composition.

### [Dry Film]

A dry film according to the present invention has a support and a resin layer made of a photosensitive resin composition provided on the described support. As an embodiment of the present invention, the dry film may be provided with a peelable protective layer on the surface of the resin layer for the purpose of preventing attachment of dust from surface of the resin layer, etc.

A support is not particularly limited and for example polyester film such as polyethylene terephthalate and polyethylene naphthalate and other films made of thermoplastic resin such as polyimide films, polyamideimide films, polypropylene films and polystyrene films can be used. Among these, polyethylene terephthalate is preferable in view of heat resistance, mechanical strength, and ease of handling. A laminate of these films may also be used as a support.

Thermoplastic films as described above are preferably uniaxially or biaxially oriented films in view of improving mechanical strength.

Thickness of the support is not particularly limited, but for example it can be 10 μm to 150 μm.

The resin layer on the support can be formed by applying the photosensitive resin composition described above to form a coating film on the support with uniform thickness by known coating methods and drying the coating film. Coating methods including comma coater, blade coater, lip coater, rod coater, squeeze coater, reverse coater, transfer roll coater, gravure coater, and spray coater can be used but not limited.

In other embodiments, the resin layer can be formed by applying and drying a photosensitive resin composition on the protective layer by the same manner described above.

Thickness of the resin layer can be changed according to the application without any particular limitation. For example, the thickness of the resin layer can be 1 to 150 μm.

The peelable protective layer on the surface of the resin layer is not limited as long as the adhesive strength between the resin layer and the protective layer is lower than the adhesive strength between the support and the resin layer when the protective layer is peeled off. For example, polyethylene film, polytetrafluoroethylene film, polypropylene film and surface treated paper can be used.

Thickness of the protective layer is not particularly limited, but for example it can be 10 to 150 μm.

### [Cured Material]

Cured material can be obtained by curing the resin layer of the photosensitive resin composition or dry film described above. The cured material may be patterned in a shape as desired. The following is an example of how to obtain the cured material but is not limited to this.

### [First Step]

Method for manufacturing cured materials according to the present invention includes the process of applying a photosensitive resin composition onto a substrate to form a coating film, and then forming a dry coating film by drying the coating film or transcribing the resin layer from the dry film described above onto the substrate.

Substrates include printed wiring boards and flexible printed wiring boards with circuits formed in advance with copper etc., paper phenol, paper epoxy, glass cloth epoxy, glass polyimide, glass cloth/nonwoven epoxy, glass cloth/paper epoxy, synthetic fiber epoxy, all grade (FR-4 etc.) of copper-clad laminates such as high frequency circuits using fluororesin, polyethylene, polyphenylene ether, polyphenylene oxide, cyanate etc., and other examples include metal substrates, polyimide film, polyethylene terephthalate film, polyethylene naphthalate (PEN) film, glass substrates, ceramic substrates, and wafer boards.

The method described above can be used as method of applying the photosensitive resin composition on the substrate.

Methods of drying the coating film include air drying, heat drying by an oven or hot plate, and vacuum drying and the like.

Drying of the coating film is desirably carried out under a condition that does not cause ring closure of the polyimide precursor in the photosensitive resin composition. Specifically, natural drying, air drying, or heat drying is preferably carried out at 70-140° C. for 1 to 3 minutes. Since the simplicity of the operation method, drying is preferably carried out by a hot plate for 1 to 20 minutes. Vacuum drying is also possible, in which case it preferably carried out at room temperature for 20 minutes to 1 hour.

Transcribing the resin layer onto the substrate is preferably carried out under pressure and heating by using a vacuum laminator. By using such a vacuum laminator, when using a circuit-formed substrate, even if the surface of the circuit board is uneven, the resin layer of the dry film fills the unevenness of the circuit board under vacuum conditions, eliminating air bubbles and improving the ability to fill holes in the surface of the board.

### [Second Step]

Next, the above coating film is exposed to active energy ray either partially through a photomask with a pattern, or entirely without a photomask.

The active energy ray should be of a wavelength that can activate, for example, a photoacid generator as a (B) photosensitizer. Specifically, the active energy ray preferably has a maximum wavelength in the range of 350 to 410 nm.

Exposure dose varies depending on the film thickness and other factors but can generally be in the range of 10 to 1000 mJ/cm², preferably 20 to 800 mJ/cm².

Exposure machine used for the above active energy ray irradiation can be any device, that equipped with high-pressure mercury lamps, ultra-high-pressure mercury lamps, metal halide lamps, mercury short-arc lamps and the like, irradiate ultraviolet rays in the 350-450 nm range. As well as direct imaging devices (for example, laser direct imaging devices that draw images directly by laser using CAD data from a computer).

### [Third Step]

If necessary, the coating film may be heated for a short time to close a portion of the polyimide precursor in the unexposed areas. Here, the ring closure rate is about 30%. The heating time and heating temperature should be changed according to the type of polyimide precursor, coating film thickness, and (B) photosensitive agent.

### [Forth Step]

Next, the coating film after the exposure described above is treated with a developer solution to remove the exposed portions in the coating film to obtain a pattern film.

In this process, development method can be selected from any conventionally known photoresist development methods, such as the inverted spray method, paddle method, soaking method with ultrasonic treatment, etc.

Developing solutions include inorganic alkalis such as sodium hydroxide, sodium carbonate, sodium silicate, and ammonia water; organic amines such as ethylamine, diethylamine, triethylamine, and triethanolamine; aqueous solutions of quaternary ammonium salts such as tetramethylammonium hydroxide, tetrabutylammonium hydroxide. If necessary, water-soluble organic solvents such as methanol, ethanol, isopropyl alcohol, etc. and surfactants may be added in appropriate quantities.

After development, the pattern film can be obtained by washing the coating film with a rinse solution if need. As a rinse solution, distilled water, methanol, ethanol, isopropyl alcohol and the like can be used alone or in combination. The above solvents may also be used as the developing solution.

### [Fifth Step]

Next, a cured coating film (cured product) can be obtained by heating the pattern film. The polyimide precursor contained in the photosensitive resin composition undergoes a cyclization reaction to become polyimide by heating process.

From the viewpoint of preventing warpage of the cured material, heating temperature is preferably 120 to 250° C., more preferably 150 to 200° C. For heating, for example, hot plates, ovens, and temperature-rising ovens with temperature settable programs can be used. Heating atmosphere (gas), may be under air or inert gas such as nitrogen or argon.

### [Applications]

Applications of the photosensitive resin composition according to the present invention are not particularly limited and the photosensitive resin composition according to the present invention are suitable for, for example, forming materials for paints, printing inks, adhesives, display devices, semiconductor devices, electronic components, optical components, and construction materials.

Specifically, forming materials of display device include layer forming materials and image forming materials in color filters, flexible display films, resist materials and alignment films.

Forming materials of semiconductor devices include layer-forming materials in resist materials, insulating films for the rewiring layer of buffer coat films and wafer-level packages (WLP) and the like.

Forming materials of electronic components include sealing materials and layer-forming materials for printed wiring boards, interlayer insulating films and wiring coating films.

Forming materials of optical components include optical materials and layer-forming materials in holograms, optical waveguides, optical circuits, optical circuit components, and antireflection films.

Furthermore, as construction materials, they can be used in paints, coating agents and the like.

The photosensitive resin composition according to the present invention are mainly used as patterning materials and particularly suitable as surface protective films, buffer coat films, interlayer insulating films, insulating films for rewiring, protective films for flip chip devices, protective films for devices with bump structures, interlayer insulating films for multilayer circuits, insulating materials for passive components, protective films for printed circuit boards such as solder resists and cover lay films, and liquid crystal alignment films.

### EXAMPLES

Hereinafter, the invention is described in more detail using examples, but the invention is not limited to the examples. In the following, “part” and “%” are all on a mass basis in so far as there is no particular remarks otherwise stated.

### Reference Example 1: Synthesis of Copolymer A-1

To a 0.5 L flask equipped with a stirrer and a thermometer, 64 g of N-methylpyrrolidone was added and 4.23 g (7.98 mmol) of 3,3′-bis(1-hydroxy-1-trifluoromethyl-2,2,2-trifluoroethyl)-4,4′-methylenedianiline (HFA-MDA) and 2.92 g (7.98 mmol) of bis(3-amino-4-(hydroxyphenyl)hexafluoropropane (6FAP) were stirred and dissolved.

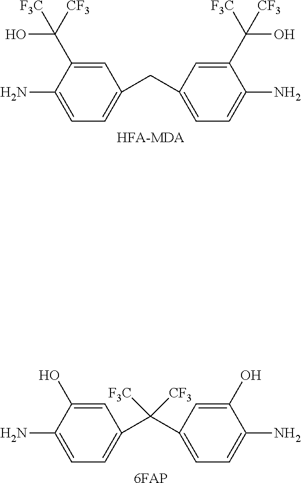

After confirming that the monomers were completely dissolved, 3.12 g (7.02 mmol) of 4,4′-(hexafluoroisopropylidene) diphthalic anhydride (6FDA) was added over 5 minutes in solid form and stirring at room temperature for 1 hour.

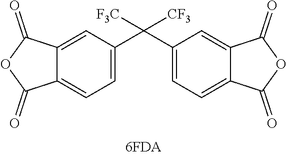 [SMILES: O=C1OC(=O)c2cc(C(c3ccc4c(c3)C(=O)OC4=O)(C(F)(F)F)C(F)(F)F)ccc21]

After that the flask was immersed in an ice bath, and while maintaining the temperature in the flask at 0° C. to 5° C., 2.07 g (7.02 mmol) of 4,4′-diphenyl ether dicarboxylic acid chloride (DEDC) was added in solid form and stirred in an ice bath for 30 minutes. After that, stirring was continued at room temperature for 4 hours.

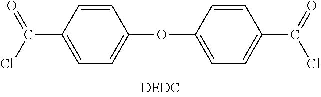 [SMILES: O=C(Cl)c1ccc(Oc2ccc(C(=O)Cl)cc2)cc1]

0.63 g (3.83 mmol) of 5-norbornene-2,3-dicarboxylic anhydride was added in solid form to the stirred solution, and the mixture was stirred at room temperature for 16 hours. The stirred solution was added into 400 mL of ion-exchanged water (resistivity value 18.2 MΩ·cm) and the precipitate was collected.

After collecting the precipitates, copolymer A-1 with the following repeating structure which has carboxyl group ends was obtained by drying the collected precipitates under reduced pressure. The number average molecular weight (Mn) of copolymer A-1 was 6,070, weight average molecular weight (Mw) was 15,780, and Mw/Mn was 2.60. In the obtained copolymer A-1, concentration of carboxyl group of was 586 g/mol, concentration hydroxyl group was 391 g/mol, concentration of fluorine was 81 g/mol.

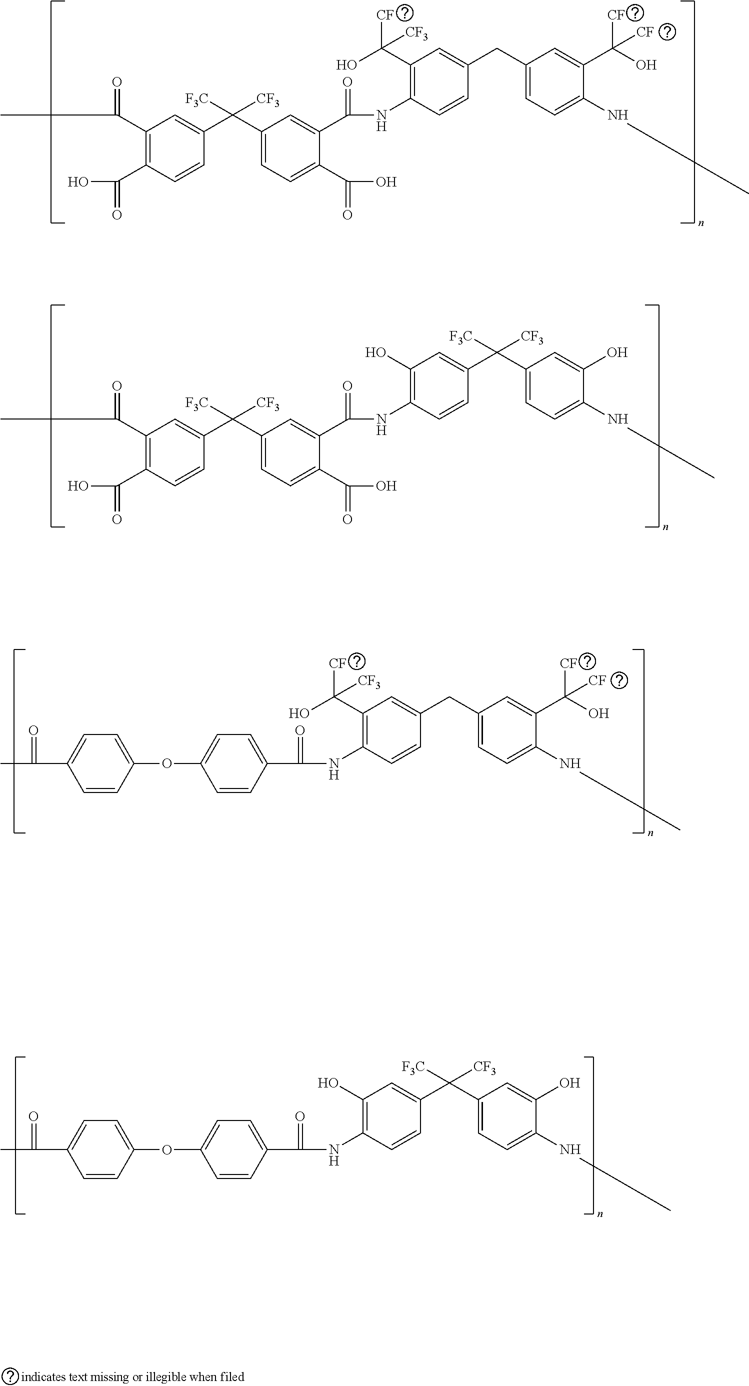

### Reference Example 2: Synthesis of Copolymer A-2

To a 0.5 L flask equipped with a stirrer and a thermometer, 69 g of N-methylpyrrolidone was added and 2.59 g (4.88 mmol) of HFA-MDA and 4.17 g (11.38 mmol) of 6FAP were stirred and dissolved.

After confirming that the monomers were completely dissolved, 5.10 g (9.62 mmol) of 5,5′-[1-methyl-1,1-ethanediylbis(1,4-phenylene)bisoxy]bis(isobenzofuran-1,3-dione) (BPADA) was added over 5 minutes in solid form and stirring at room temperature for 1 hour.

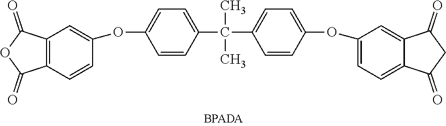 [SMILES: CC(C)(c1ccc(Oc2ccc3c(c2)C(=O)CC3=O)cc1)c1ccc(Oc2ccc3c(c2)C(=O)OC3=O)cc1]

After that the flask was immersed in an ice bath, and while maintaining the temperature in the flask at 0° C. to 5° C., 1.22 g (4.12 mmol) of DEDC was added in solid form and stirred in an ice bath for 30 minutes. After that, stirring was continued at room temperature for 4 hours. 0.82 g (5.01 mmol) of 5-norbornene-2,3-dicarboxylic anhydride was added in solid form to the stirred solution and the mixture was stirred at room temperature for 16 hours. The stirred solution was added into 400 mL of ion-exchanged water (resistivity value 18.2 MΩ·cm) and the precipitate was collected.

After collecting the precipitates, copolymer A-2 with the following repeating structure which has carboxyl group ends was obtained by drying the collected precipitates under reduced pressure. The number average molecular weight (Mn) of copolymer A-2 was 5,000, weight average molecular weight (Mw) was 13,150, and Mw/Mn was 2.63. In the obtained copolymer A-2, concentration of carboxyl group of was 550 g/mol, concentration hydroxyl group was 423 g/mol, concentration of fluorine was 54 g/mol.

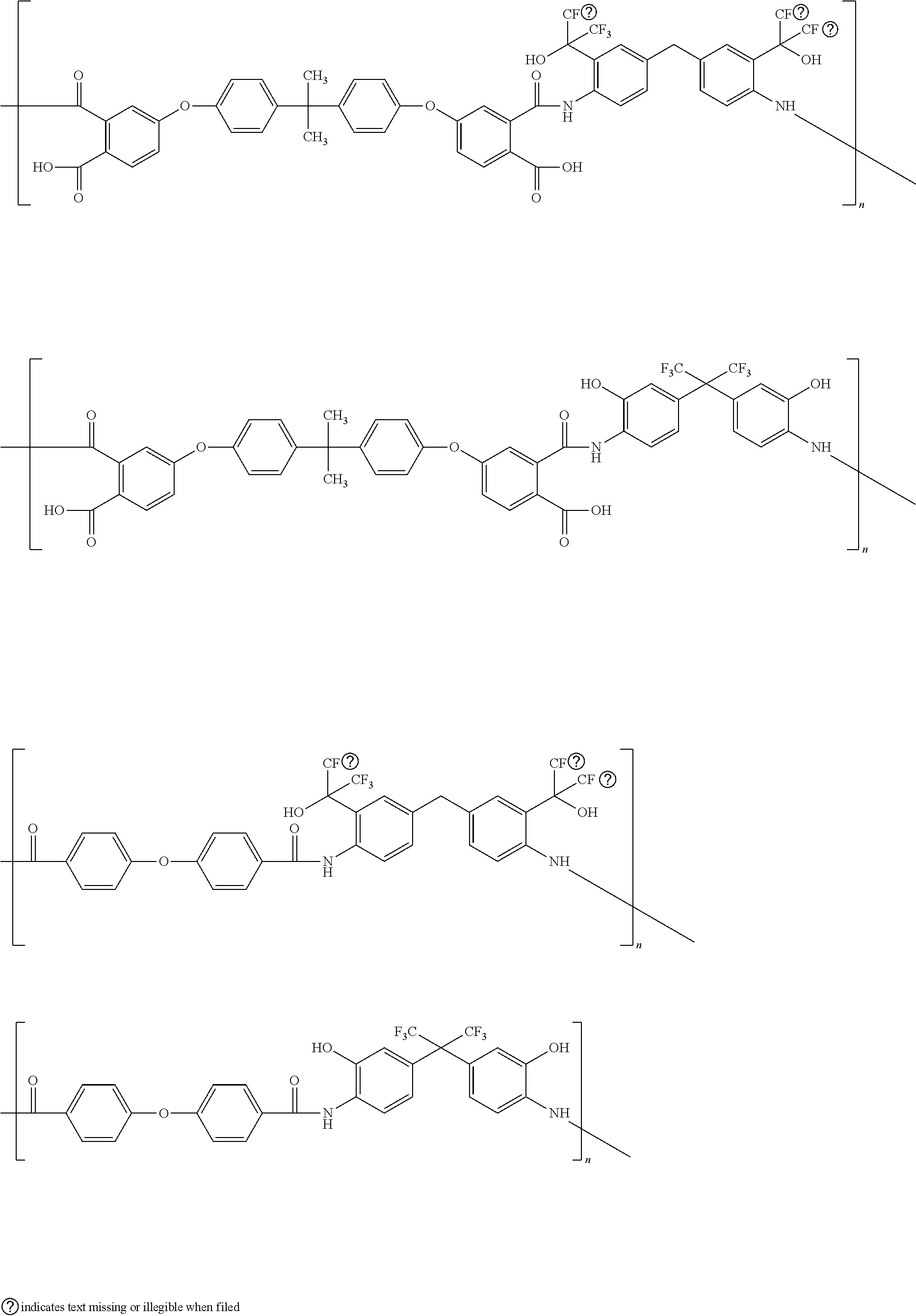

### Reference Example 3: Synthesis of Copolymer A-3

To a 0.5 L flask equipped with a stirrer and a thermometer, 62 g of N-methylpyrrolidone was added and 5.85 g (11.04 mmol) of HFA-MDA and 1.73 g (4.73 mmol) of 6FAP were stirred and dissolved.

After confirming that the monomers were completely dissolved, 1.32 g (4.27 mmol) of oxydiphthalic anhydride (ODPA) was added over 5 minutes in solid form and stirring at room temperature for 1 hour.

After that the flask was immersed in an ice bath, and while maintaining the temperature in the flask at 0° C. to 5° C., 2.94 g (9.96 mmol) of DEDC was added in solid form and stirred in an ice bath for 30 minutes. After that, stirring was continued at room temperature for 4 hours. 0.51 g (3.09 mmol) of 5-norbornene-2,3-dicarboxylic anhydride was added in solid form to the stirred solution, and the mixture was stirred at room temperature for 16 hours. The stirred solution was added into 400 mL of ion-exchanged water (resistivity value 18.2 MΩ·cm) and the precipitate was collected.

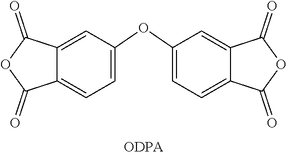 [SMILES: O=C1OC(=O)c2cc(Oc3ccc4c(c3)C(=O)OC4=O)ccc21]

After collecting the precipitates, copolymer A-3 with the following repeating structure which has carboxyl group ends was obtained by drying the collected precipitates under reduced pressure. The number average molecular weight (Mn) of copolymer A-3 was 7,080, weight average molecular weight (Mw) was 18,120, and Mw/Mn was 2.56. In the obtained copolymer A-3, concentration of carboxyl group of was 621 g/mol, concentration hydroxyl group was 365 g/mol, concentration of fluorine was 74 g/mol.

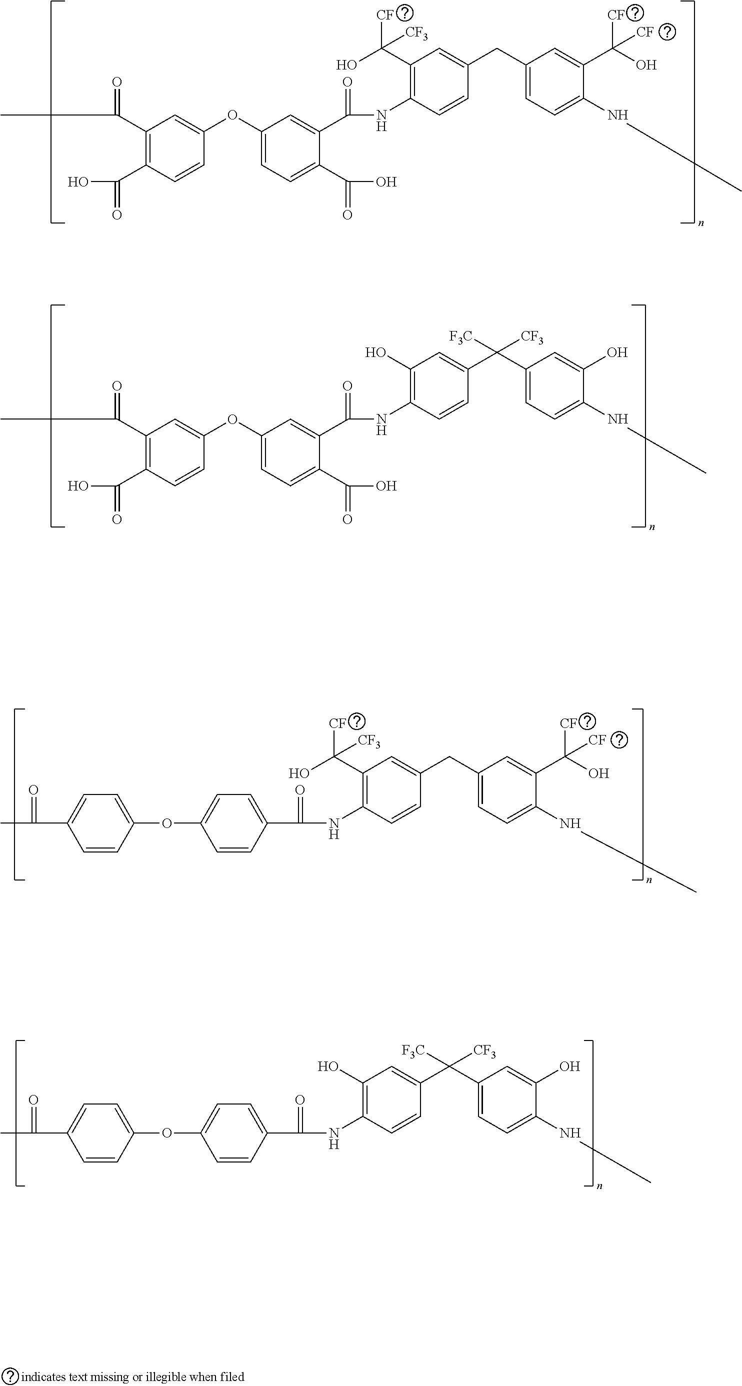

### Reference Example 4: Synthesis of Copolymer A-4

To a 0.5 L flask equipped with a stirrer and a thermometer, 60 g of N-methylpyrrolidone was added and 4.26 g (8.04 mmol) of HFA-MDA and 2.94 g (8.04 mmol) of 6FAP was stirred and dissolved.

After confirming that the monomers were completely dissolved, the flask was immersed in an ice bath, and while maintaining the temperature in the flask at 0° C. to 5° C., 4.11 g (13.92 mmol) of DEDC was added in solid form and stirred in an ice bath for 30 minutes. After that, stirring was continued at room temperature for 4 hours. 0.71 g (4.31 mmol) of 5-norbornene-2,3-dicarboxylic anhydride was added in solid form to the stirred solution and the mixture was stirred at room temperature for 16 hours. The stirred solution was added into 400 mL of ion-exchanged water (resistivity value 18.2 MΩ·cm) and the precipitate was collected.

After collecting the precipitates, copolymer A-4 with the following repeating structure which has carboxyl group ends was obtained by drying the collected precipitates under reduced pressure. The number average molecular weight (Mn) of copolymer A-4 was 3,990, weight average molecular weight (Mw) was 10,090, and Mw/Mn was 2.53. In the obtained copolymer A-4, concentration of carboxyl group of was 0 g/mol, concentration hydroxyl group was 336 g/mol, concentration of fluorine was 82 g/mol.

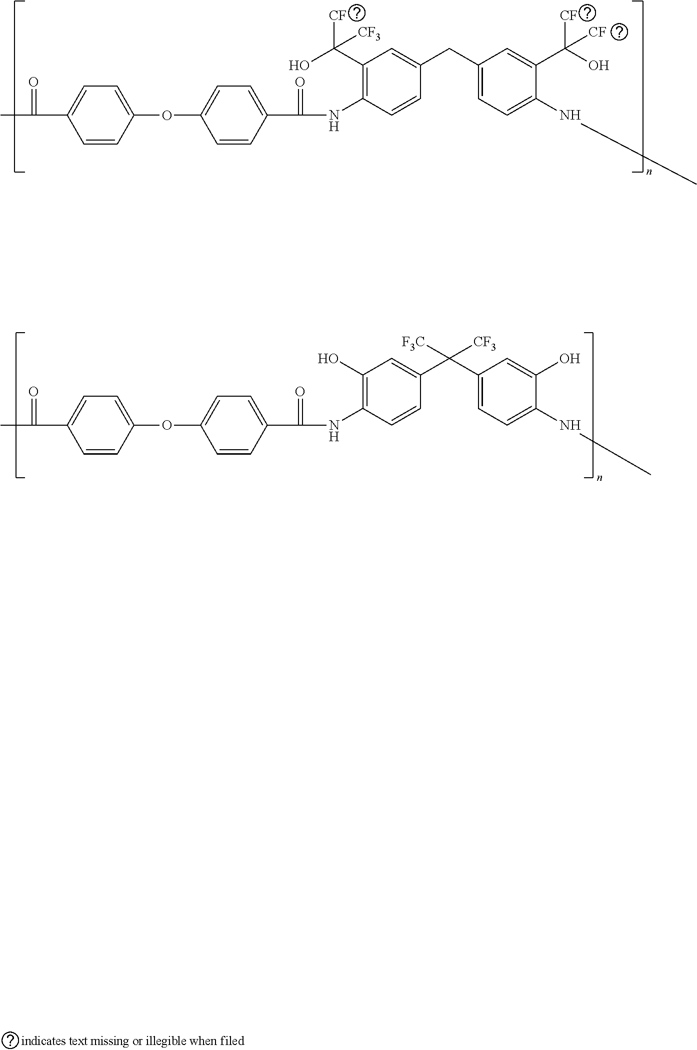

### Reference Example 5: Synthesis of Copolymer A-5

To a 0.5 L flask equipped with a stirrer and a thermometer, 53 g of N-methylpyrrolidone was added and 13.95 g (26.30 mmol) of HFA-MDA was stirred and dissolved.

After confirming that the monomers were completely dissolved, 13.95 g (26.30 mmol) of 5,5T-[1-methyl-1,1-ethanediylbis(1,4-phenylene)bisoxy]bis(isobenzofuran-1,3-dione) (BPADA) was added over 5 minutes in solid form and stirring at room temperature for 1 hour.

After that 0.85 g (5.19 mmol) of 5-norbornene-2,3-dicarboxylic anhydride was added in solid form to the stirred solution, and the mixture was stirred at room temperature for 16 hours. The stirred solution was added into 1 L of ion-exchanged water (resistivity value 18.2 MΩ·cm) and the precipitate was collected.

After collecting the precipitates, copolymer A-5 with the following repeating structure which has norbornene ends was obtained by drying the collected precipitates under reduced pressure. The number average molecular weight (Mn) of copolymer A-5 was 6,800, weight average molecular weight (Mw) was 16,790, and Mw/Mn was 2.47. In the obtained copolymer A-5, concentration of carboxyl group of was 525 g/mol and concentration of fluorine was 88 g/mol.

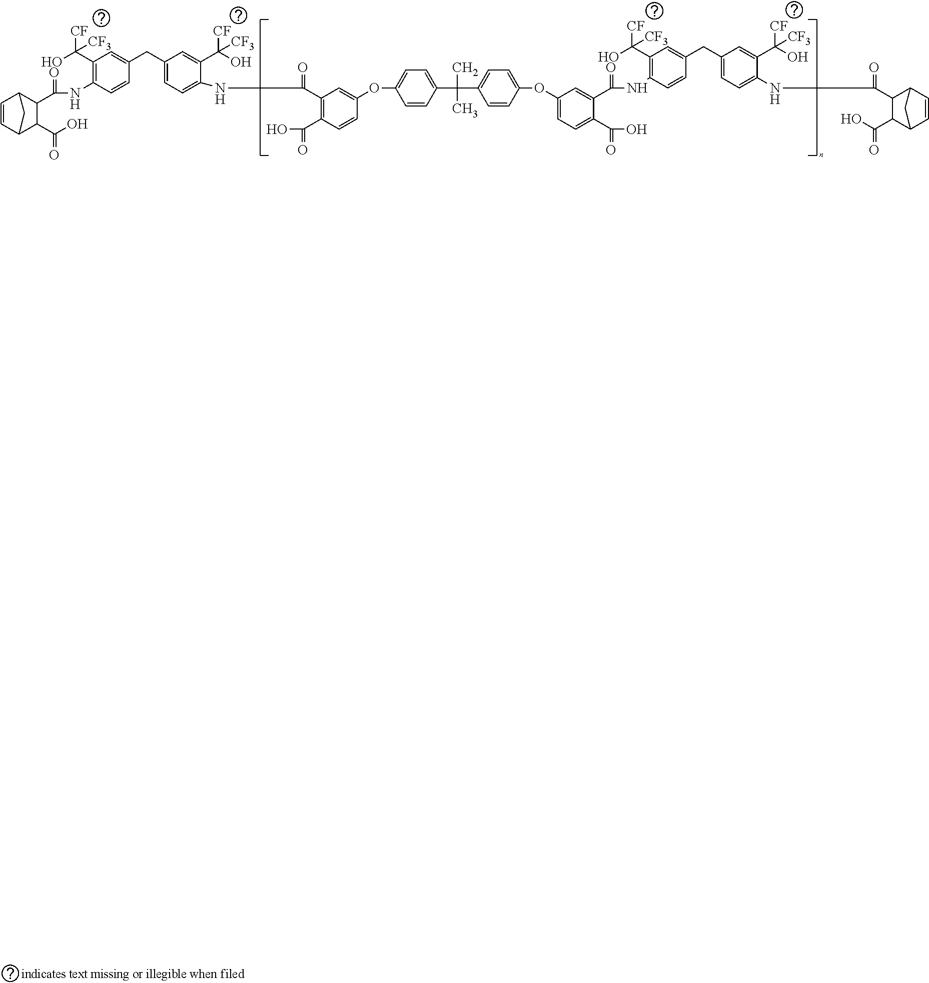

### Reference Example 6: Synthesis of Copolymer A-6

To a 0.5 L flask equipped with a stirrer and a thermometer, 53 g of N-methylpyrrolidone was added and 14.40 g (26.45 mmol) of HFA-MDA was stirred and dissolved.

After confirming that the monomers were completely dissolved, 10.46 g (23.55 mmol) of 6FDA was added over 10 minutes in solid form and stirring at room temperature for 1 hour. After that, 0.96 g (5.82 mmol) of 5-norbornene-2,3-dicarboxylic anhydride was added in solid form to the stirred solution and the mixture was stirred at room temperature for 16 hours.

The stirred solution was added into 1 L of ion-exchanged water (resistivity value 18.2 MΩ·cm) and the precipitate was collected.

After collecting the precipitates, copolymer A-6 with the following repeating structure which has norbornene ends was obtained by drying the collected precipitates under reduced pressure. The number average molecular weight (Mn) of copolymer A-6 was 8,700, weight average molecular weight (Mw) was 22,100, and Mw/Mn was 2.54. In the obtained copolymer A-6, concentration of carboxyl group of was 494 g/mol and concentration of fluorine was 55 g/mol.

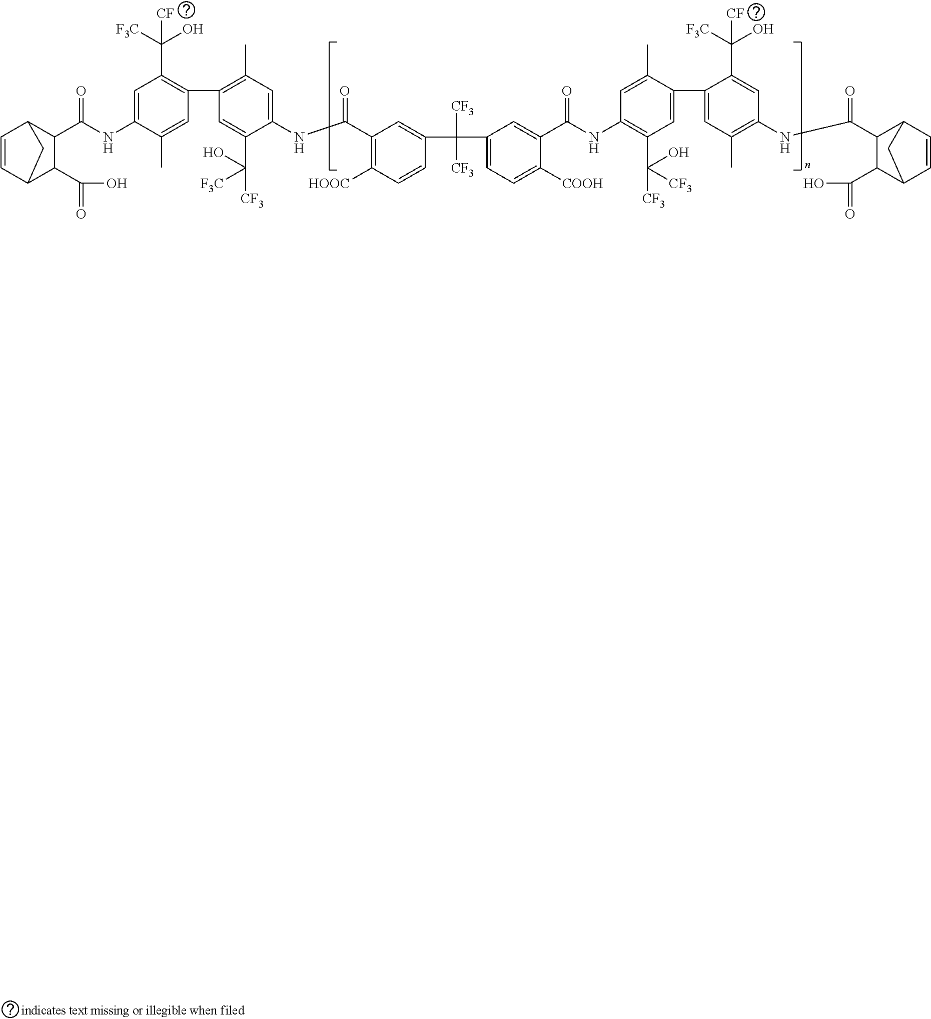

### Reference Example 7: Synthesis of Copolymer A-7

To a 0.5 L flask equipped with a stirrer and a thermometer, 150 g of N-methylpyrrolidone was added and 8.43 g (15.91 mmol) of HFA-MDA was stirred and dissolved.

After confirming that the monomers were completely dissolved, 1.88 g (4.23 mmol) of 6FDA and 5.14 g (9.87 mmol) of BPADA were added over 10 minutes in solid form and stirring at room temperature for 1 hour.

0.59 g (3.62 mmol) of 5-norbornene-2,3-dicarboxylic anhydride was added in solid form to the stirred solution, and the mixture was stirred at room temperature for 16 hours.

The stirred solution was added into 1 L of ion-exchanged water (resistivity value 18.2 MΩ·cm) and the precipitate was collected.

After collecting the precipitates, copolymer A-7 with the following repeating structure which has norbornene ends was obtained by drying the collected precipitates under reduced pressure. The number average molecular weight (Mn) of copolymer A-7 was 9,500, weight average molecular weight (Mw) was 24,800, and Mw/Mn was 2.61. In the obtained copolymer A-7, concentration of carboxyl group of was 514 g/mol and concentration of fluorine was 73 g/mol.

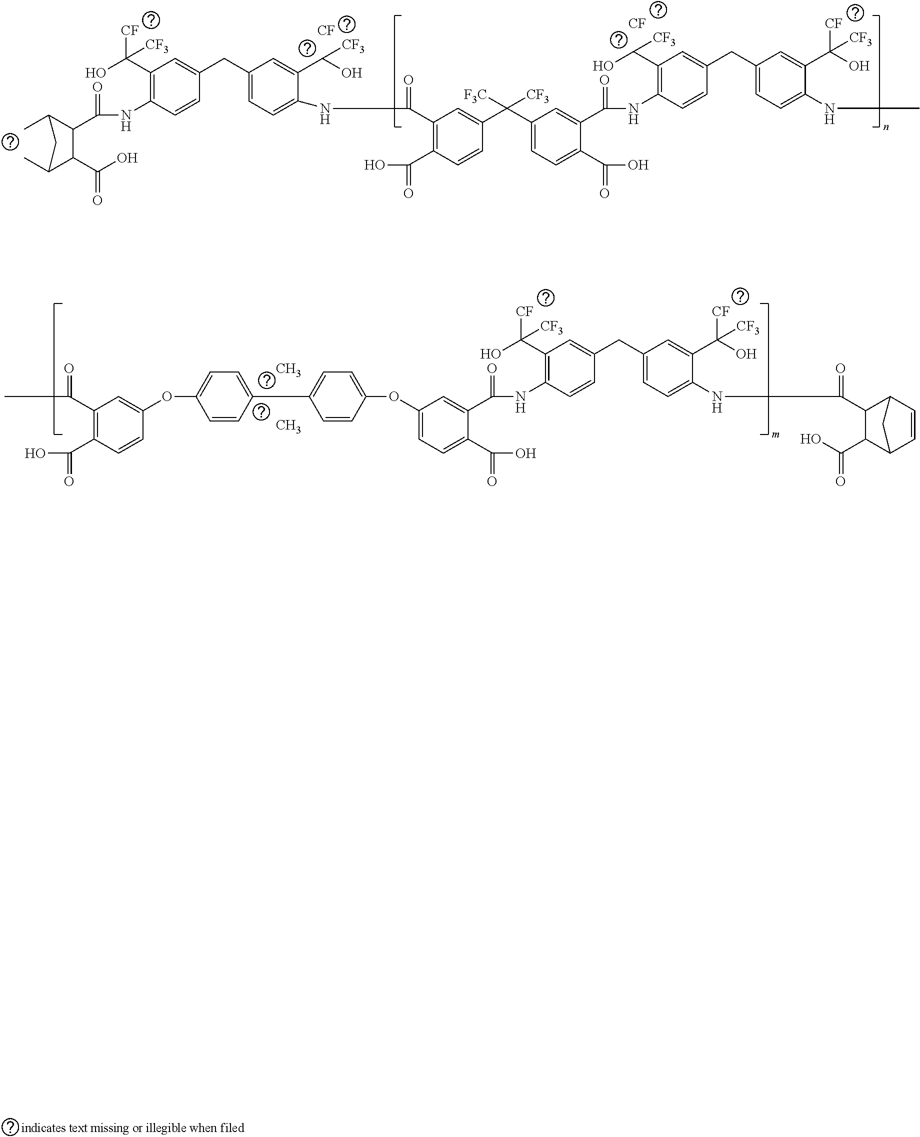

### Reference Example 8: Synthesis of Copolymer A-8

To a 0.5 L flask equipped with a stirrer and a thermometer, 150 g of N-methylpyrrolidone was added and 8.33 g (15.71 mmol) of HFA-MDA was stirred and dissolved.

After confirming that the monomers were completely dissolved, 1.33 g (4.29 mmol) of ODPA and 5.21 g (10.01 mmol) of BPADA were added over 10 minutes in solid form and stirring at room temperature for 1 hour.

0.46 g (2.82 mmol) of 5-norbornene-2,3-dicarboxylic anhydride was added in solid form to the stirred solution and the mixture was stirred at room temperature for 16 hours. The stirred solution was added into 1 L of ion-exchanged water (resistivity value 18.2 MΩ·cm) and the precipitate was collected.

After collecting the precipitates, copolymer A-8 with the following repeating structure which has carboxyl group ends was obtained by drying the collected precipitates under reduced pressure. The number average molecular weight (Mn) of copolymer A-8 was 10,200, weight average molecular weight (Mw) was 24,680, and Mw/Mn was 2.42. In the obtained copolymer A-8, concentration of carboxyl group of was 494 g/mol and concentration of fluorine was 82 g/mol.

### Reference Example 9: Synthesis of Copolymer A-9

To a 0.5 L flask equipped with a stirrer and a thermometer, 100 g of N-methylpyrrolidone was added and 5.16 g (25.75 mmol) of diaminodiphenyl ether was stirred and dissolved.

After confirming that the monomers were completely dissolved, 5.29 g (24.25 mmol) of pyromellitic anhydride (PMDA) was added over 5 minutes in solid form and stirring at room temperature for 1 hour. 0.49 g (2.98 mmol) of 5-norbornene-2,3-dicarboxylic anhydride was added in solid form to the stirred solution, and the mixture was stirred at room temperature for 16 hours. The stirred solution was added into 600 mL of ion-exchanged water (resistivity value 18.2 MΩ·cm) and the precipitate was collected.

After collecting the precipitates, copolymer A-9 with the following repeating structure which has carboxyl group ends was obtained by drying the collected precipitates under reduced pressure. The number average molecular weight (Mn) of copolymer A-9 was 6,800, weight average molecular weight (Mw) was 17,000, and Mw/Mn was 2.51. In the obtained copolymer A-9, concentration of carboxyl group of was 210 g/mol, concentration hydroxyl group was 0 g/mol, the concentration of fluorine was 0 g/mol.

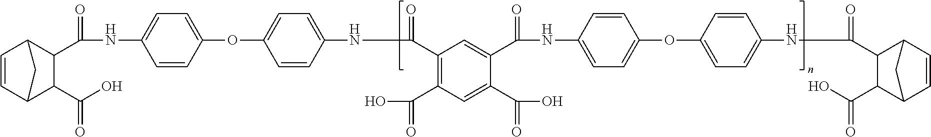

### Reference Example 10: Synthesis of Polybenzoxazole Precursor

In a 0.5 L flask equipped with a stirrer and a thermometer, 10.0 g (27.3 mmol) of bis (3-amino-4-hydroxyphenyl) hexafluoropropane was stirred and dissolved into 1500 g of N-methylpyrrolidone.

After that the flask was immersed in an ice bath, and while maintaining the temperature in the flask at 0° C. to 5° C., 8.78 g (29.8 mmol) of 4,4′-diphenyl ether dicarboxylic acid chloride was added over 10 minutes in solid form and stirred in an ice bath for 30 minutes.

The mixture was stirred at room temperature for 18 hours. The stirred solution was added into 700 mL of ion-exchanged water (resistivity value 18.2 MΩ·cm) and the precipitate was collected.

After that, the solid obtained was dissolved into 420 mL and added into 1 L of ion-exchanged water (resistivity value 18.2 MΩ·cm) and the precipitate was collected. After collecting the precipitates, polybenzoxazole precursor which has carboxyl group ends was obtained by drying the collected precipitates under reduced pressure. Mw was 29,500, Mn was 11,600, and Mw/Mn was 2.54. In the obtained polybenzoxazole precursor, the concentration of carboxyl group of was 0 g/mol, the concentration hydroxyl group was 295 g/mol, the concentration of fluorine was 98 g/mol.

For each of the copolymers A-1 to A-10 obtained as described above, the ratios of constituent components (diamine component, dicarboxylic acid component) are summarized in Table 1.

TABLE 1

| | Content in copolymers (mol %) | | | | | | | |
|---|---|---|---|---|---|---|---|---|
| Table 1 | HFA-MDA | ODA | 6FAP | 6FDA | BPADA | ODPA | PMDA | DEDC |
| Copolymer A-1 | 25 | — | 25 | 25 | — | — | — | 25 |
| Copolymer A-2 | 15 | — | 35 | — | 35 | — | — | 15 |
| Copolymer A-3 | 35 | — | 15 | — | — | 15 | — | 15 |
| Copolymer A-4 | 25 | — | 25 | — | — | — | — | 50 |
| Copolymer A-5 | 50 | — | — | — | 50 | — | — | — |
| Copolymer A-6 | 50 | — | — | 50 | — | — | — | — |
| Copolymer A-7 | 50 | — | — | 15 | 35 | — | — | — |
| Copolymer A-8 | 50 | — | — | | 35 | 15 | — | — |
| Copolymer A-9 | — | 50 | — | — | — | — | 50 | — |
| Copolymer A-10 | — | — | 50 | — | — | — | — | 50 |

### Example 1

A varnish containing the photosensitive resin composition was obtained by mixing 100 parts by mass of copolymer A-1 obtained in Reference Example 1 described above, 20 parts by mass of naphthoquinone diazide compound (manufactured by Sanbo Chemical Ind. Co., Ltd., TKF-528), 5 parts by mass of adhesive agent (manufactured by Shin-Etsu Chemical Co., Ltd. KBM-573), and 400 parts by mass of PGMEA in a light-shielding container.

### Examples 2-4 and Comparative Examples 1-2

As shown in Table 2, varnishes were obtained in the same manner as in Example 1, except that the copolymer A-1 was changed to the copolymers A-2 to A-4, A-9, and A-10, respectively.

### <Solubility Evaluation>

The varnishes obtained in the above examples and those obtained in the comparative examples were visually observed and their solubility was evaluated based on the following evaluation criteria. The evaluation results are shown in Table 2.

The solvent was changed to 4-methyl-2-pentanone (MIBK) and the solubility was evaluated in the same way as above. The results are shown in Table 2.

### (Evaluation Criteria)

∘: No residual solution (precipitate) was found, and the varnish was not cloudy.
Δ: No residual solution was found, but the varnish was turbid.
x: Remnants of solution were present.

### <Dissolution Rate Evaluation>

The varnishes obtained in the above Examples and those obtained in the Comparative Examples 1-2, in which PGMEA was changed to γ-butyrolactone, were prepared.

The varnishes were coated on a silicon substrate with a film thickness of approximately 2 μm by using a spin coater.

Then the coating was dried at 110° C. for 3 minutes by using a hot plate to obtain a dry coating film. Half of the coating film was exposed to 200 mJ/cm² of i-ray irradiation by using a high-pressure mercury vapor lamp. After the exposure, the samples were immersed into a 2.38% tetramethylammonium hydroxide (TMAH) solution and the time to dissolve was measured. The dissolution rate was measured by using the following formula and the dissolution rate of exposed and unexposed areas was evaluated based on the following evaluation criteria. The evaluation results are shown in Table 2.

In addition, the dissolution contrast (dissolution rate of exposed area/dissolution rate of unexposed area) was determined from the obtained dissolution rate of the exposed area and the unexposed area and was evaluated based on the following evaluation criteria. The evaluation results are shown in Table 2.

Dissolution Rate=initial film thickness (nm)/dissolution time (s)

### (Evaluation Criteria of Dissolution Rate of the Exposed Area)

⊚: Dissolution Rate is 500 nm/s or more and 1000 nm/s or less.
∘: Dissolution Rate is 200 nm/s or more and less than 500 nm/s.
x: Dissolution Rate is less than 200 nm/s or more than 1000 nm/s.

### (Evaluation Criteria of Dissolution Rate of the Unexposed Area)

⊚: Dissolution Rate is less than 5 nm/s.

∘: Dissolution Rate is 5 nm/s or more and less than 20 nm/s.

x: Dissolution Rate is 20 nm/s or more.

### (Evaluation Criteria of Dissolution Contrast)

⊚: Dissolution contrast is 200 or more.

∘: Dissolution contrast is 100 or more, less than 200.

x: Dissolution contrast is less than 200.

### <Resolution Evaluation>

As in the dissolution rate evaluation above, varnishes obtained in the above examples and those obtained in Comparative Examples 1-2 in which PGMEA was changed to γ-butyrolactone were prepared.

The varnishes were coated on a silicon substrate with a film thickness of approximately 2 μm by using a spin coater.

Then the coating was dried at 110° C. for 3 minutes by using a hot plate to obtain a dry coating film. The coating film was exposed to 200 mJ/cm² of broad light by using a high-pressure mercury vapor lamp through a mask with an engraved pattern. After the exposure, the samples were immersed into a 2.38% tetramethylammonium hydroxide (TMAH) solution for 60 seconds to developed and rinsed with water to obtain a positive pattern film.

The L/S (line/space) of the pattern engraved on the mask was changed successively from 1 μm/1 μm to 30 μm/30 μm (where L=S and L and S is an integer) and determined minimum of L/S that is possible to form a positive pattern film that allows patterning of the exposed area without scum (development residue) by observing with electron microscope (SEM “JSM 6010”). A resolution was evaluated by calculating the lowest L/S value based on the following evaluation criteria. The evaluation results are shown in Table 2.

### (Evaluation Criteria)

⊚: Even when the L/S of the pattern is 2 μm/2 μm, it was possible to form a positive pattern film that allows patterning of the exposed area without scum (development residue).
∘: When the L/S of the pattern is 2 μm/2 μm, it was not possible to form a positive pattern film that allows patterning of the exposed area without scum (development residue) but when the L/S of the pattern is 3 μm/3 μm, it is possible.
Δ: When the L/S of the pattern is 3 μm/3 μm, it was not possible to form a positive pattern film that allows patterning of the exposed area without scum (development residue) but when the L/S of the pattern is 5 μm/5 μm, it is possible.
x: When the L/S of the pattern is 5 μm/5 μm, it was not possible to form a positive pattern film that allows patterning of the exposed area without scum (development residue).

### <Storage Stability Evaluation>

The varnishes obtained in the above Examples and those obtained in Comparative Examples 1-2, in which PGMEA was changed to γ-butyrolactone, were prepared.

The viscosities of the varnishes were determined by a cone-plate viscometer (manufactured by Toki Sangyo Co., Ltd., TPE-100, 50 rpm, 25° C.).

Then the varnishes were kept in a thermostatic chamber at 4° C. for 7 days, and the viscosity after 7 days was measured in the same manner, the rate of change in viscosity was calculated and storage stability thereof was evaluated based on the following evaluation criteria. The evaluation results are shown in Table 2.

⊚: Rate of change is less than 5%.

∘: Rate of change is 5% or more and less than 10%.

x: Rate of change is 10% or more and less than 15%.

TABLE 2

| | | Concentration | Concentration | | | |
|---|---|---|---|---|---|---|
| | | of Carboxyl | of Hydroxyl | Concentration | Solubility | |
| | | Group | Group | of Fluorine | of Solvent | |
| Table 2 | Copolymer | (g/mol) | (g/mol) | (g/mol) | PGMEA | MIBK |
| Example 1 | A-1 | 586 | 391 | 81 | ◯ | ◯ |
| Example 2 | A-2 | 550 | 423 | 54 | ◯ | ◯ |
| Example 3 | A-3 | 621 | 365 | 74 | ◯ | ◯ |
| Example 4 | A-4 | — | 336 | 82 | ◯ | ◯ |
| Comparative | A-9 | 210 | — | — | X | X |
| Example 1 | | | | | | |
| Comparative | A-10 | — | 295 | 98 | X | Δ |
| Example 2 | | | | | | |
| | | Dissolution | Dissolution | | | |
| | | Rate in | Rate in | | | |
| | | Exposed | Unexposed | Dissolution | | Storage |
| | | Area | Area | Contrast | Resolution | Stability |
| | Table 2 | Evaluation | Evaluation | Evaluation | Evaluation | Evaluation |
| | Example 1 | ⊚ | ◯ | ○ | ◯ | ◯ |
| | Example 2 | ⊚ | ◯ | ○ | ⊚ | ◯ |
| | Example 3 | ⊚ | ⊚ | ⊚ | ⊚ | ⊚ |
| | Example 4 | ◯ | ⊚ | ⊚ | ⊚ | ⊚ |
| | Comparative | X | X | X | Δ | X |
| | Example 1 | | | | | |
| | Comparative | X | ⊚ | ○ | Δ | ⊚ |
| | Example 2 | | | | | |

### Examples 5 to 8

As shown in Table 3, varnishes were obtained in the same manner as in Example 1, except that the copolymer A-1 was changed to the copolymers A-5 to A-8.

In Examples A-5 to A-8, solubility evaluation, dissolution rate evaluation, and resolution evaluation were performed in the same manner as above. The glass transition temperature (Tg) was also measured as follows. The evaluation results are shown in Table 3.

### <Measurement of Glass Transition Temperature (Tg)>

As in the above dissolution rate evaluation, the varnishes obtained in the above Examples and those obtained in Comparative Examples 1-2, in which PGMEA was changed to γ-butyrolactone, were prepared.

The varnishes were coated on a silicon substrate by using a spin coater. Then the coating was dried at 110° C. for 3 minutes by using a hot plate and after heated at 110° C. for 10 minutes under a nitrogen atmosphere, held at 320° C. for 30 minutes and then heated at 320° C. for 60 minutes in an inert gas oven (manufactured by Koyo Thermo System Co., Ltd. CLH-21CD-S), cured film with a film thickness of approximately 10 μm was obtained. The obtained cured film was peeled off from the substrate and Tg was measured by DSC manufactured by TA Instrument.

TABLE 3

| | | Concentration | | | | Dissolution | Dissolution | | | |
|---|---|---|---|---|---|---|---|---|---|---|
| | | of Carboxyl | Concentration | Solubility | | Rate in | Rate in | Dissolution | | |
| | | Group | of Fluorine | of Solvent | | Exposed Area | Unexposed | Contrast | Resolution | Tg |
| Table 3 | Copolymer | (g/mol) | (g/mol) | PGMEA | MIBK | Evaluation | Area Evaluation | Evaluation | Evaluation | (° C.) |
| Example 5 | A-5 | 525 | 88 | ◯ | ◯ | ◯ | ⊚ | ◯ | ◯ | 240 |
| Example 6 | A-6 | 494 | 55 | ◯ | ◯ | ⊚ | ◯ | ◯ | ◯ | 235 |
| Example 7 | A-7 | 514 | 73 | ◯ | ◯ | ⊚ | ⊚ | ⊚ | ⊚ | 230 |
| Example 8 | A-8 | 494 | 82 | ◯ | ◯ | ⊚ | ⊚ | ⊚ | ⊚ | 210 |
| Comparative | A-9 | 210 | — | X | X | X | X | X | Δ | 240 |
| Example 1 | | | | | | | | | | |
| Comparative | A-10 | — | 98 | X | Δ | X | ⊚ | ◯ | Δ | 260 |
| Example 2 | | | | | | | | | | |

As is clear from the evaluation results shown in Tables 1-3, it was found that a photosensitive resin composition according to the present invention has excellent dissolution rate in the exposed area and dissolution contrast and has high resolution.

In addition, it was found that the photosensitive resin composition according to the present invention has a high storage stability.

It was also found that the polyimide precursor used in the photosensitive resin composition according to the present invention has high solubility in low boiling point solvents such as PGMEA and 4-methyl-2-pentanone.

Furthermore, it was found that the cured materials formed by the photosensitive resin composition according to the present invention have high Tg and excellent heat resistance.

1: A photosensitive resin composition, comprising:
a polyimide precursor; and
a photosensitive agent,
wherein the polyimide precursor is a reaction product of dicarboxylic acid and diamine compound comprising at least one selected from the group consisting of compounds of formulae (1) and (2), 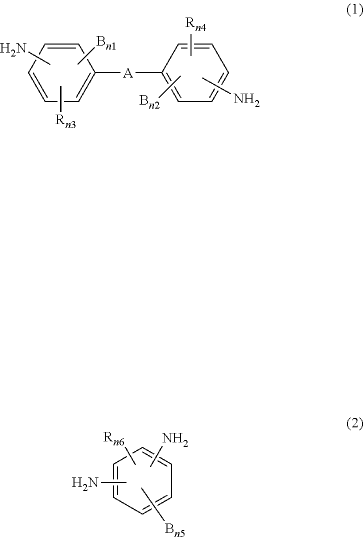
where A is selected from the group consisting of single bond, O and divalent organic groups, B is fluoroalcohol groups, R is substituted or unsubstituted alkyl groups or substituted or unsubstituted aryl groups, each of n1 and n2 is independently an integer in a range of 0 to 4 such that n1+n2 is not less than 1, each of n3 and n4 is independently an integer in a range of 0 to 3, n5 is an integer in a range of 1 to 4, and n6 is an integer in a range of 0 to 3, and the dicarboxylic acid is at least one selected from the group consisting of carboxylic anhydrides and dicarboxylic chlorides.

2: The photosensitive resin composition according to claim 1, wherein the diamine compound further comprises at least one selected from the group consisting of compounds of formulae (3) and (4), 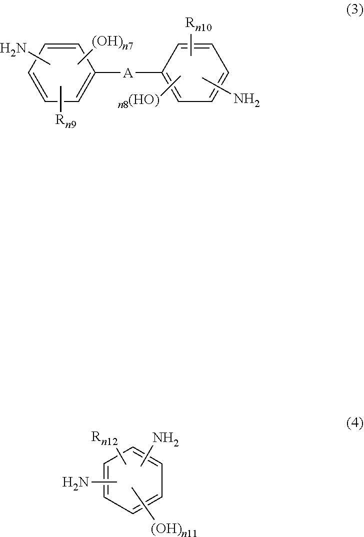
where A is selected from the group consisting of single bond, O and divalent organic groups, R is substituted or unsubstituted alkyl groups or substituted or unsubstituted aryl groups, each of n7 and n8 is independently an integer in a range of 0 to 4 such that n7+n8 is not less than 1, each of n9 and n10 is independently an integer in a range of 0 to 3, n11 is an integer in a range of 1 to 4, and n12 is an integer in a range of 0 to 3.

3: The photosensitive resin composition according to claim 1, wherein a fluorine concentration of the polyimide precursor is in a range of 20 to 200 mol/g.

4: The photosensitive resin composition according to claim 1, wherein a carboxyl group concentration of the polyimide precursor is in a range of 300 to 800 mol/g.

5: The photosensitive resin composition according to claim 1, wherein a hydroxyl group concentration of the polyimide precursor is in a range of 200 to 600 mol/g.

6: The photosensitive resin composition according to claim 1, wherein a number of carbon in each of the fluoroalcohol groups in the formulae (1) and (2) is independently in a range of 1 to 10, and a number of fluorine in each of the fluoroalcohol groups in the formulae (1) and (2) is independently in a range of 1 to 10.

7: The photosensitive resin composition according to claim 1, further comprising:
an adhesion agent.

8: The photosensitive resin composition according to claim 1, wherein the photosensitive agent is a naphthoquinone diazide compound.

9: A dry film, comprising:
a film; and
a resin layer formed on the film,
wherein the resin layer is formed of the photosensitive resin composition of claim 1.

10: A cured material formed of the photosensitive resin composition of claim 1.

11: An electronic component, comprising:
the cured material of claim 10.

12: A cured material, comprising:
a resin layer of the dry film of claim 9.

13: The photosensitive resin composition according to claim 2, wherein a fluorine concentration of the polyimide precursor is in a range of 20 to 200 enol/g.

14: The photosensitive resin composition according to claim 2, wherein a carboxyl group concentration of the polyimide precursor is in a range of 300 to 800 mol/g.

15: The photosensitive resin composition according to claim 2, wherein a hydroxyl group concentration of the polyimide precursor is in a range of 200 to 600 mol/g.

16: The photosensitive resin composition according to claim 2, wherein a number of carbon in each of the fluoroalcohol groups in the formulae (1) and (2) is independently in a range of 1 to 10, and a number of fluorine in each of the fluoroalcohol groups in the formulae (1) and (2) is independently in a range of 1 to 10.

17: The photosensitive resin composition according to claim 2, further comprising:
an adhesion agent.

18: The photosensitive resin composition according to claim 2, wherein the photosensitive agent is a naphthoquinone diazide compound.

19: The photosensitive resin composition according to claim 3, wherein a carboxyl group concentration of the polyimide precursor is in a range of 300 to 800 mol/g.

20: The photosensitive resin composition according to claim 3, wherein a hydroxyl group concentration of the polyimide precursor is in a range of 200 to 600 enol/g.
